(19) United States
(12) Patent Application Publication
(10) Pub. No.: US 2024/0429165 A1
(43) Pub. Date: Dec. 26, 2024

(54) SEMICONDUCTOR DEVICE

(71) Applicant: SAMSUNG ELECTRONICS CO., LTD., Suwon-si (KR)

(72) Inventors: Dongsik PARK, Suwon-si (KR); Jihoon CHANG, Suwon-si (KR)

(73) Assignee: SAMSUNG ELECTRONICS CO., LTD., Suwon-si (KR)

(21) Appl. No.: 18/656,076

(22) Filed: May 6, 2024

(30) Foreign Application Priority Data
Jun. 21, 2023 (KR) 10-2023-0079397

(51) Int. Cl. H01L 23/528; H01L 29/49; H10B 12/00

(52) U.S. Cl. CPC H01L 23/5283; H01L 29/495; H10B 12/315; H10B 12/488; H10B 12/50

(57) ABSTRACT

A semiconductor device may include a lower wiring structure on a substrate, the lower wiring structure including a plurality of wirings. The plurality of wirings includes a first wiring group having a first stacked structure including a metal pattern and a barrier metal pattern constituting a contact plug and a conductive pattern, and the barrier metal pattern surrounding a lower surface of the metal pattern; and a second wiring group having a second stacked structure different from the first stacked structure, the second stacked structure including a lower metal pattern and a lower barrier metal pattern surrounding a lower surface of the lower metal pattern constituting the contact plug, and an upper metal pattern constituting the conductive pattern, the upper metal pattern having a resistance lower than the lower metal pattern.

### CROSS-REFERENCE TO RELATED APPLICATION

This application is based on and claims priority under 35 USC § 119 to Korean Patent Application No. 10-2023-0079397, filed on Jun. 21, 2023, in the Korean Intellectual Property Office (KIPO), the contents of which being incorporated by reference herein in their entirety.

### BACKGROUND

### 1. Field

An example embodiment of the disclosure relate to a semiconductor device and in particular, a semiconductor device including a vertical channel transistor.

### 2. Description of Related Art

Recently, semiconductor devices are being manufactured in a highly integrated manner. As such, in order to achieve high integration, a semiconductor device may include the vertical channel transistor including a channel provided in a vertical direction perpendicular to a surface of a substrate. The semiconductor device may include wirings for electrically connecting memory cells and core/peripheral circuits to each other.

### SUMMARY

An example embodiment provides a semiconductor device including a vertical channel transistor and a wiring structure.

According to an aspect of the disclosure, there is provided a semiconductor device including: a first wiring structure on a substrate, the first wiring structure including a plurality of wirings, each of the plurality of wirings including a contact plug and a conductive pattern stacked in a vertical direction perpendicular to a surface of the substrate; and a cell structure provided on an uppermost conductive pattern in the first wiring structure, the cell structure including a vertical channel transistor connected to the conductive pattern, wherein the plurality of wirings of the first wiring structure includes: a first wiring group including one or more first wirings, among the plurality of wirings, having a first stacked structure, the first stacked structure including a metal pattern and a barrier metal pattern constituting the contact plug and the conductive pattern, and the barrier metal pattern surrounding a lower surface of the metal pattern; and a second wiring group including one or more second wirings, among the plurality of wirings, having a second stacked structure different from the first stacked structure, the second stacked structure including a lower metal pattern and a lower barrier metal pattern surrounding a lower surface of the lower metal pattern constituting the contact plug, and an upper metal pattern constituting the conductive pattern, the upper metal pattern having a resistance lower than the lower metal pattern.

According to another aspect of the disclosure, there is provided a semiconductor device including: a first wiring structure on a substrate, the first wiring structure including a plurality of wirings, each of the plurality of wirings including a contact plug and a conductive pattern stacked in a vertical direction perpendicular to a surface of the substrate; a channel pattern provided on the first wiring structure, the channel pattern including two or more sidewalls extending in the vertical direction and a lower surface connecting lower portions of two opposing sidewalls, among the two or more sidewalls, in a horizontal direction, the lower surface of the channel pattern contacting an uppermost conductive pattern in the first wiring structure; a gate insulation layer pattern and a word line pattern laterally stacked on an inner wall of the channel pattern; and a capacitor connected to an upper surface of the channel pattern, wherein the plurality of wirings of the first wiring structure includes: a first wiring group including one or more first wirings, among the plurality of wirings, having a first stacked structure, the first stacked structure including a metal pattern and a barrier metal pattern constituting the contact plug and the conductive pattern, and the barrier metal pattern surrounding a lower surface of the metal pattern; and a second wiring group including one or more second wirings, among the plurality of wirings, having a second stacked structure different from the first stacked structure, the second stacked structure including a lower metal pattern and a lower barrier metal pattern surrounding a lower surface of the lower metal pattern constituting the contact plug, and an upper metal pattern constituting the conductive pattern, the upper metal pattern formed by a physical vapor deposition process.

According to another aspect of the disclosure, there is provided a semiconductor device, including: a peripheral circuit structure including a plurality of peripheral circuits provided on a substrate; a first wiring structure including a plurality of wirings connected to the plurality of peripheral circuit structures, each of the plurality of wirings including a contact plug and a conductive pattern stacked in a vertical direction perpendicular to the surface of the substrate, and an uppermost conductive pattern in the first wiring structure having a line shape extending in a first direction parallel with a surface of the substrate; a channel pattern provided on the first wiring structure, the channel pattern including two or more sidewalls extending in the vertical direction and a lower surface connecting lower portions of two opposing sidewalls, among the two or more sidewalls, in a horizontal direction, and the channel pattern regularly arranged in the first direction and a second direction perpendicular to the first direction, the lower surface of the channel pattern contacting an uppermost conductive pattern in the first wiring structure; a word line pattern formed laterally on an inner wall of the channel pattern, the word line extending in the second direction; a gate insulation layer pattern between the channel pattern and the word line, the gate insulation layer pattern extending in the second direction; and a capacitor connected to an upper surface of the channel pattern, wherein the plurality of wirings of the first wiring structure includes: a first wiring group including one or more first wirings, among the plurality of wirings, having a first stacked structure, the first stacked structure including a metal pattern and a barrier metal pattern constituting the contact plug and the conductive pattern, and the barrier metal pattern surrounding a lower surface of the metal pattern; and a second wiring group including one or more second wirings, among the plurality of wirings, having a second stacked structure different from the first stacked structure, the second stacked structure including a lower metal pattern formed by a chemical vapor deposition process and a lower barrier metal pattern surrounding a lower surface of the lower metal pattern constituting the contact plug, and an upper metal pattern formed by a physical vapor deposition process constituting the conductive pattern.

In the semiconductor device according to an example embodiment, the lower wiring structure may include at least one a first group wiring and at least one a second group wiring. Therefore, the lower wiring structure may have low resistance, and electrical characteristics of the semiconductor device may be improved.

### BRIEF DESCRIPTION OF DRAWINGS

An example embodiment will be more clearly understood from the following detailed description taken in conjunction with the accompanying drawings. FIGS. 1 to 29 represent non-limiting, an example embodiment as described herein.

FIG. 1 is a block diagram of a semiconductor device according to an example embodiment;

FIG. 2 is a perspective view schematically illustrating a semiconductor device according to an example embodiment;

FIG. 3 is a cross-sectional view of a semiconductor device according to an example embodiment;

FIG. 4 is a plan view of cell structures in a semiconductor device according to an example embodiment;

FIG. 5 is an enlarged cross-sectional view of a lower wiring structure in a semiconductor device according to according to an example embodiment;

FIG. 6 is an enlarged cross-sectional view of a lower wiring structure in a semiconductor device according to an example embodiment;

FIG. 7 is an enlarged cross-sectional view of a lower wiring structure in a semiconductor device according to an example embodiment;

FIG. 8 is an enlarged cross-sectional view of a lower wiring structure in a semiconductor device according to an example embodiment;

FIGS. 9 to 27 are cross-sectional views of stages in a method of manufacturing a semiconductor device according to an example embodiment;

FIG. 28 is an enlarged cross-sectional view of a lower wiring structure in a semiconductor device according to an example embodiment; and

FIG. 29 is an enlarged cross-sectional view of a lower wiring structure in a semiconductor device according to an example embodiment.

### DETAILED DESCRIPTION

Hereinafter, various embodiments will be described in detail with reference to the accompanying drawings.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

Hereinafter, a direction parallel to a surface of a substrate is referred to as a first direction, and a direction parallel to the surface of the substrate and perpendicular to the first direction is referred to as a second direction. In addition, a direction perpendicular to the surface of the substrate is referred to as a vertical direction.

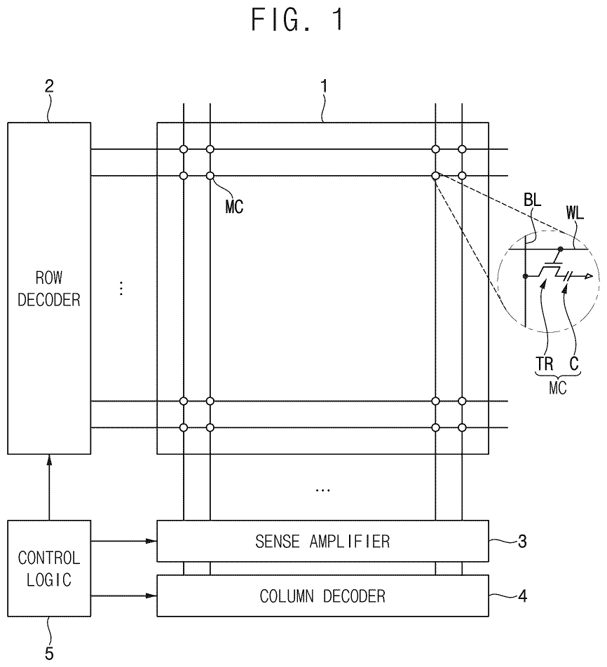

FIG. 1 is a block diagram of a semiconductor device according to an example embodiment.

Referring to FIG. 1, the semiconductor device may include a memory cell array 1, a row decoder 2, a sense amplifier 3, a column decoder 4, and a control logic 5.

The memory cell array 1 may include a plurality of memory cells MC. Each of the memory cells MC may be positioned at a cross point of word lines WL and bit lines BL, and may be connected to one of the word lines WL and one of the bit lines BL.

Unit memory cell MC may include a transistor TR and a capacitor C. A gate electrode included in the transistor TR may extend in a direction parallel to an upper surface of the substrate 100, and may serve as the word line WL. A drain region of the transistor TR may be electrically connected to the bit line BL and a source region of the transistor TR may be electrically connected to the capacitor C.

The row decoder 2 may decode an input address, and may select one of the word lines WL in the memory cell array 1. An address decoded in the row decoder 2 may be provided to a row driver. The row driver may apply a predetermined voltage to selected word lines WL and unselected word lines WL, respectively, based on signals of a control logic 5.

The sense amplifier 3 may detect and amplify a voltage difference between a selected bit line BL and a reference bit line according to an address decoded in the column decoder 4, and may output an amplified voltage difference between the selected bit line BL and the reference bit line.

The column decoder 4 may be a data transmission path between the sense amplifier 3 and an external device (e.g., a memory controller). The column decoder 4 may decode an external input address, and thus may select one of the bit lines BL.

The control logic 5 may generate control signals for writing or reading data into the memory cell array 1. According to an embodiment, the control logic 5 may be implemented as a control logic circuit.

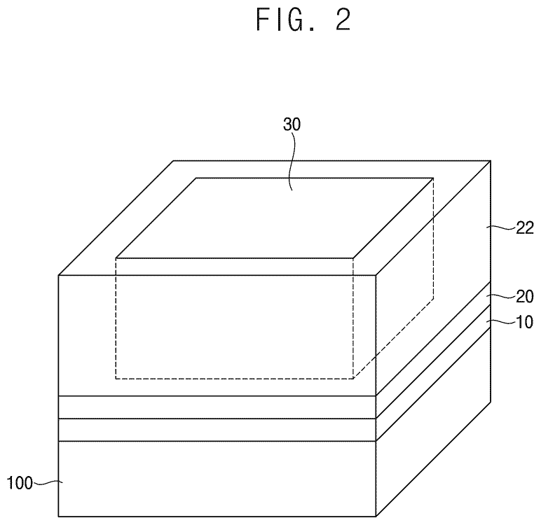

FIG. 2 is a perspective view schematically illustrating a semiconductor device according to an example embodiment.

Referring to FIG. 2, a peripheral circuit structure 10, a lower wiring structure 20, and a cell structure 30 may be sequentially stacked on a semiconductor substrate 100. A wiring structure 22 electrically connected to the lower wiring structure 20 may be further provided outside the cell structure 30.

The peripheral circuit structure 10 may include core circuits and peripheral circuits formed on the semiconductor substrate 100. The core circuits and peripheral circuits may include the row decoder 2, column decoder 4, the sense amplifier 3, and the control logic 5 as illustrated in FIG. 1.

The cell structure 30 may be provided on the peripheral circuit structure 10. The cell structure 30 may include the memory cells MC (FIG. 1) connected to the bit lines and the word lines. The memory cells may be arranged on a plane extending in the first direction and the second direction. Each of the memory cells MC may include the transistor TR (and the capacitor C as illustrated in FIG. 1.

The transistor included in each of the memory cells may include a vertical channel transistor (VCT). The vertical channel transistor may include a channel pattern extending in the vertical direction.

The lower wiring structure 20 may be provided between the peripheral circuit structure 10 and the cell structure 30 in the vertical direction. The lower wiring structure 20 may electrically connect the peripheral circuit structure 10 and the cell structure 30.

In an example embodiment, the bit lines may be positioned below the channel pattern of the vertical channel transistor. The word lines may be positioned on sidewalls of the channel pattern of the vertical channel transistor.

The sense amplifier on the substrate 100 may be electrically connected to the bit lines. In an example embodiment, the sense amplifier and the bit lines may be electrically connected by portions of the lower wiring structure 20 on the substrate 100. In an example embodiment, uppermost conductive patterns included in the lower wiring structure 20 may serve as the bit lines, and thus the lower wiring structure 20 may include the bit lines.

In an example embodiment, wiring structures formed on the substrate 100, and the wiring structure may be electrically connected to the word lines. Thus, the wiring structures may be electrically connected to the peripheral circuit structure 10 corresponding to the row driver of the row decoder via the word lines. Additionally, a wiring structure connected to the control logic may be further formed on the substrate 100. In an example embodiment, at least one of the wiring structures may be provided outside the cell structure 30. According to an example embodiment, at least one of the wiring structures may not overlap the cell structure 30 in the vertical direction.

As described above, an arrangement of the lower wiring structure 20 for connecting the peripheral circuit structure 10 and the memory cells may be complicated. Therefore, the lower wiring structure 20 may not be composed of a single layer wiring, and instead the lower wiring structure 20 may be composed of a multi-layer wiring. Additionally, the lower wiring structure 20 may be designed to have a low resistance.

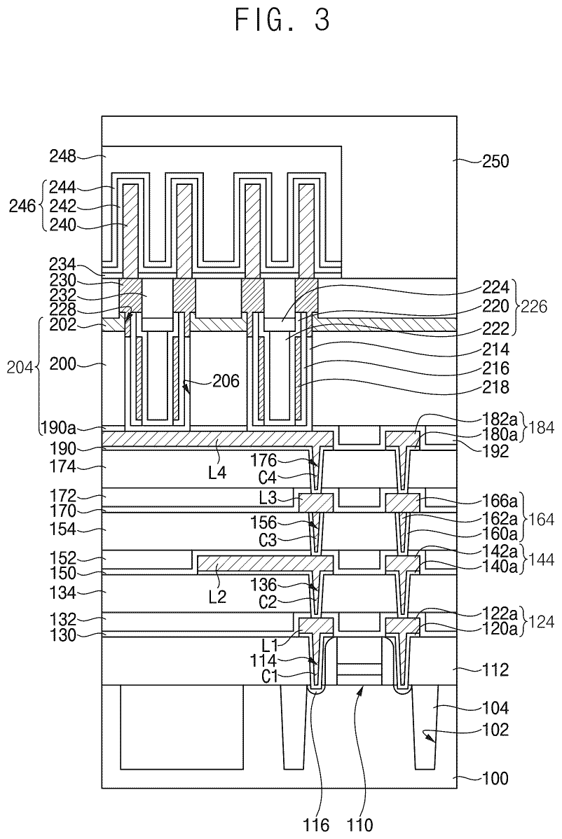

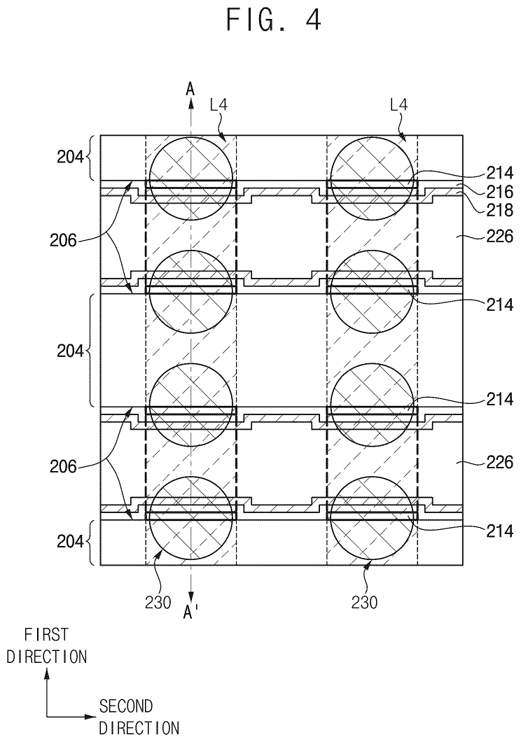

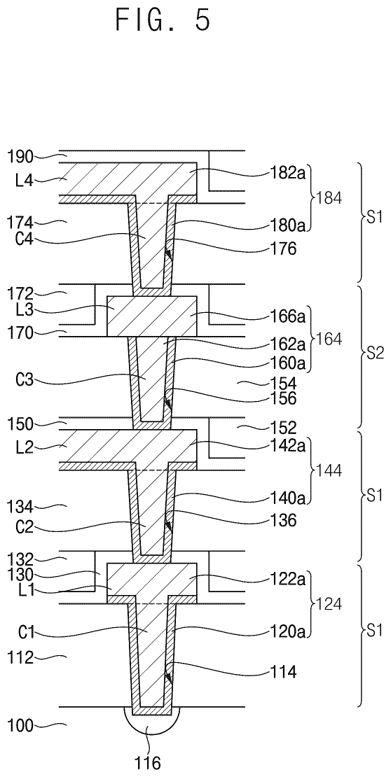

FIG. 3 is a cross-sectional view of a semiconductor device according to an example embodiment. FIG. 4 is a plan view of cell structures in a semiconductor device according to an example embodiment. FIG. 5 is an enlarged cross-sectional view of a lower wiring structure in a semiconductor device according to according to an example embodiment.

The semiconductor device illustrated in FIG. 3 may be a DRAM device. However, the disclosure is not limited thereto, and as such, the semiconductor device may be another type of electronic device. FIG. 3 shows a bit line, and cell structures provided on the bit line taken along line A-A′ of FIG. 4. In FIG. 4, a capacitor and elements formed on the capacitor are omitted to avoid complexity of drawing.

According to an example embodiment illustrated in FIGS. 3 to 5, the semiconductor device may include a peripheral circuit structure on a substrate 100. The peripheral circuit structure may include peripheral transistors 110 constituting peripheral circuits. The peripheral transistors 110 may include an NMOS transistor and a PMOS transistor. The peripheral transistor 110 may be a planar type transistor. Although only one peripheral transistor 110 is provided on the substrate 100 in FIG. 3, a plurality of peripheral transistors constituting the peripheral circuits may be provided on the substrate 100.

According to an example embodiment, a trench 102 may be formed on the substrate 100, and an isolation pattern 104 may be filled in the trench 102. The peripheral transistor 110 may be formed on the isolation pattern 104 and the substrate 100. The peripheral transistor 110 may include a lower gate structure and impurity regions. The lower gate structure may include a lower gate insulation layer, a lower gate electrode, and a hard mask pattern. The lower gate insulation layer, the lower gate electrode, and the hard mask pattern may be in a stacked arrangement. The impurity regions may be formed at an upper portion of the substrate 100 adjacent to both sides of the lower gate structure.

A lower wiring structure may be provided on the peripheral circuit structure. The lower wiring structure may have a structure in which wirings are stacked in a plurality of layers. For example, the lower wiring structure may include a first wiring 124, a second wiring 144, a third wiring 164 and a fourth wiring 184. However, the disclosure is not limited to four wirings, and such, according to another embodiment, the lower wiring structure may include a number of wirings different than four. Each of the wirings included in the lower wiring structure may include a contact plug and a conductive pattern. Hereinafter, the lower wiring structure including the first to fourth wirings 124, 144, 164, and 184 may be described.

According to an example embodiment, a first lower insulating interlayer 112 may be provided on the substrate 100. For example, the first lower insulating interlayer 112 may be provided on the peripheral transistor 110. For example, the first lower insulating interlayer 112 may be provided to cover the peripheral transistor 110 on the substrate 100. The first lower insulating interlayer 112 may include silicon oxide. However, the disclosure is not limited thereto.

A first contact hole 114 may pass through the first lower insulating interlayer 112. The first contact hole 114 may pass through the first lower insulating interlayer 112 and contact the substrate 100. The first contact hole 114 may expose the impurity regions of the peripheral transistor 110. The first contact hole 114 may also expose an upper surface of the substrate 100. The first wiring 124 may be provided on the first lower insulating interlayer 112. Moreover, the first wiring 124 may be provided in the first contact hole 114, and as such, the first wiring 124 may fill the first contact hole 114. The first wiring 124 may be a lowermost wiring directly contacting the substrate 100.

The first wiring 124 may include a first contact plug C1 and a first conductive pattern L1. The first contact plug C1 may fill the first contact hole 114. The first conductive pattern L1 may be provided on the first contact plug C1 and the first lower insulating interlayer 112, and may be connected to the first contact plug C1. The first conductive pattern L1 may be in direct contact with the first contact plug C1. The first conductive pattern L1 may extend in a direction parallel to an upper surface of the substrate 100. For example, the first conductive pattern L1 may extend one of the first and second directions.

In an example embodiment, a metal silicide pattern 116 may be further included between the first contact plug C1 and the substrate 100.

The first wiring 124 may include a first barrier metal pattern 120a and a first metal pattern 122a provided on the first barrier metal pattern. The first barrier metal pattern 120a may be provided along an inner surface of the first contact hole 114 and an upper surface of the first lower insulating interlayer 112. The first metal pattern 122a may be provided in the contact hole 114. For example, the first metal pattern 122a may fill the first contact hole 114.

The first metal pattern 122a may contact an entire upper surface of the first barrier metal pattern 120a. However, the disclosure is not limited thereto, and as such, according to another embodiment, the first metal pattern 122a may contact at least a portion of an upper surface of the first barrier metal pattern 120a. According to an embodiment, the first contact plug C1 and the first conductive pattern L1 may include the first metal pattern 122a having one body. As such, a distinct connect portion (e.g., an interface) may not be provided between the first contact plug C1 and the first conductive pattern L1. That is, the first contact plug C1 and the first conductive pattern L1 including the first metal pattern 122a may be formed as a one-piece structure. The first barrier metal pattern 120a may be provided on a bottom of the first metal pattern 122a, and may contact the bottom of the first metal pattern 122a.

Hereinafter, in each of wirings including the contact plug and the conductive pattern, the first stacked structure may include the metal pattern having one body (i.e., one piece structure) and the barrier metal pattern, constituting the contact plug and the conductive pattern. As illustrated in FIG. 5, in the first stacked structure S1, the barrier metal pattern may surround a lower surface of the metal pattern. In the first stacked structure S1, the barrier metal pattern may extend to the surface of the contact hole and the upper surface of the lower insulating interlayer, and the connect portion between the contact plug and the conductive pattern formed as a metal having the one body. In the first stacked structure S1, the barrier metal layer pattern may be formed on a lower surface of the metal pattern, and may contact the lower surface of the metal pattern.

In an example embodiment, the first wiring 124, which is the lowest wiring directly contacting the substrate 100, may have the first stacked structure S1.

The barrier metal pattern and the metal pattern included in the wiring having the first stacked structure S1 may be formed by a chemical vapor deposition process. The barrier metal pattern included in the wiring having the first stacked structure S1 may include, but is not limited to, titanium, titanium nitride, tantalum, tantalum nitride, tungsten nitride, tungsten carbon nitride, or the like.

The metal pattern included in the wiring having the first stacked structure S1 may include a metal material that can be patterned by an etching process, and may include a material with a low thermal budget in processes for forming a cell structure thereon. The metal pattern included in the wiring having the first stacked structure S1 may include, but is not limited to, tungsten or aluminum. For example, the metal pattern included in the wiring having the first stacked structure S1 may include tungsten formed by the chemical vapor deposition process.

In an example embodiment, a first etch stop layer 130 may be provided on the first lower insulating interlayer 112 and the first wiring 124. For example, the first etch stop layer 130 may conform to the upper surfaces of the first lower insulating interlayer 112 and the first wiring 124, and cover the surfaces of the first lower insulating interlayer 112 and the first wiring 124. The first etch stop layer 130 may include, but is not limited to silicon nitride.

In an example embodiment, a second lower insulating interlayer 132 and a third lower insulating interlayer 134 may be formed on the first etch stop layer 130. In an example embodiment, the second lower insulating interlayer 132 may fill a gap between the first conductive patterns L1. The third lower insulating interlayer 134 may be provided on the second lower insulating interlayer 132 and the first etch stop layer 130.

The second lower insulating interlayer 132 may include silicon oxide. The third lower insulating interlayer 134 may include silicon nitride. However, the material included in each of the second and third lower insulating interlayers 132 and 134 may not be limited thereto. For example, the second and third lower insulating interlayers 132 and 134 may include the same material. Also, the second and third lower insulating interlayers 132 and 134 may include a material other than silicon oxide or silicon nitride.

In an example embodiment, second contact holes 136 may pass through the third lower insulating interlayers 134, and may expose an upper surface of the first wiring 124. A second wiring 144 may be provided on the third lower insulating interlayer 134 to fill the second contact hole 136.

The second wiring 144 may include a second contact plug C2 and a second conductive pattern L2. The second contact plug C2 may be provided in the second contact hole 136. The second contact plug C2 may fill the second contact hole 136. The second conductive pattern L2 may be provided on the second contact plug C2 and the third lower insulating interlayer 134, and may be electrically connected to the second contact plug C2. The second conductive pattern L2 may extend in a direction parallel to the upper surface of the substrate 100.

In an example embodiment, the second wiring 144 may include a second barrier metal pattern 140a and a second metal pattern 142a provided on the second barrier metal pattern 140a. The second barrier metal pattern 140a may be formed along an inner surface of the second contact hole 136 and an upper surface of the third lower insulating interlayer 134. The second metal pattern 142a may be provided in the second contact hole 136. The second metal pattern 142a may fill the second contact hole 136, and an upper surface of the second metal pattern 142a may be positioned over the third lower insulating interlayer 134. In this case, the second wiring 144 may have the first stacked structure S1.

In an example embodiment, a second etch stop layer 150 may be provided on the third lower insulating interlayer 134 and the second wiring 144. For example, the second etch stop layer 150 may conformally cover the surfaces of the third lower insulating interlayer 134 and the second wiring 144. The second etch stop layer 150 may include, but is not limited to, silicon nitride.

In an example embodiment, a fourth lower insulating interlayer 152 and a fifth lower insulating interlayer 154 may be formed on the second etch stop layer 150. In an example embodiment, the fourth lower insulating interlayer 152 may fill the gap between the second conductive patterns L2. The fifth lower insulating interlayer 154 may be provided on the fourth lower insulating interlayer 152 and the second etch stop layer 150.

The fourth lower insulating interlayer 152 may include silicon oxide, and the fifth lower insulating interlayer 154 may include silicon nitride. However, the materials included in the fourth and fifth lower insulating interlayers 152 and 154 may not be limited thereto. For example, the fourth and fifth lower insulating interlayers 152 and 154 may include the same material. Also, the fourth and fifth lower insulating interlayers 152 and 154 may include a material other than silicon oxide or silicon nitride.

In an example embodiment, third contact holes 156 may pass through the fifth lower insulating interlayer 154, and may expose an upper surface of the second wiring 144. A third wiring 164 may be provided on the fifth lower insulating interlayer 154 to fill the third contact hole 156.

The third wiring 164 may include a third contact plug C3 and a third conductive pattern L3. The third contact plug C3 may be provided in the third contact hole 156. The third contact plug C3 may fill the third contact hole 156. The third conductive pattern L3 may be formed on the third contact plug C3 and the fifth lower insulating interlayer 154, and may be electrically connected to the third contact plug C3. The third conductive pattern L3 may extend in a direction parallel to the upper surface of the substrate 100.

The third contact plug C3 includes a third barrier metal pattern 160a and a third metal pattern 162a provided on the third barrier metal pattern 160a. The third barrier metal pattern 160a may be formed along an inner surface of the third contact hole 156. The third metal pattern 162a may be provided in the third contact hole 156. The third metal pattern 162a may fill the third contact hole 156. In an embodiment, an upper surface of the third metal pattern 162a and an upper surface of the fifth lower insulating interlayer 154 may be at a same level. However, the disclosure is not limited thereto, and as such, according to another embodiment, an upper surface of the third metal pattern 162a may be positioned over the fifth lower insulating interlayer 154 or below the fifth lower insulating interlayer 154.

The third conductive pattern L3 may include a fourth metal pattern 166a. The fourth metal pattern 166a may be independent and/or distinct from the third metal pattern 162a. For example, the fourth metal pattern 166a may have a resistance lower than a resistance of the third metal pattern 162a.

In the third wiring 164, the third barrier metal pattern 160a may be only on the sidewall and bottom of the third contact hole 156. The third barrier metal pattern 160a may not be formed on the upper surface of the fifth lower insulating interlayer 154. Additionally, a connect portion (e.g., an interface) between the third metal patterns 162a included in the third contact plug C3 and the fourth metal pattern 166a serving as the third conductive pattern L3 may be generated. That is, the connect portion between the third and fourth metal patterns 162a and 166a may be distinguished. For example, the third and fourth metal patterns 162a and 166a may be independent and/or distinct from each other. For example, the third and fourth metal patterns 162a and 166a may be formed as a two-piece structure.

As illustrated in FIG. 5, in the wiring including the contact plug and the conductive pattern, a second stacked structure S2 may include a lower metal pattern and a barrier metal pattern surrounding a lower surface of the lower metal pattern constituting the contact plug, and an upper metal pattern constituting the conductive pattern. In the second stacked structure S2, the barrier metal pattern may be formed only on the surface of the contact hole, and the connection portion between contact plug and the conductive pattern may be distinguished. For example, the contact plug and the conductive pattern may be independent and/or distinct from each other. For example, the contact plug and the conductive pattern may be formed as a two-piece structure. The third wiring 164 may have the second stacked structure S2. In the second stacked structure S2, a material of the conductive pattern may have a resistance lower than a resistance of a material of the contact plug.

In the case of the wiring having the second stacked structure S2, a lower metal pattern included in the contact plug, and an upper metal pattern included in the conductive pattern may be formed by different deposition processes.

The lower metal pattern included in the contact plug may be formed by a deposition process having excellent gap filling characteristic, and the upper metal pattern included in the conductive pattern may be formed by a deposition process for depositing a material with high purity and low resistance. In the case of the wiring having the second stacked structure S2, the upper metal pattern included in the conductive pattern may be formed by a physical vapor deposition process. Additionally, in the case of the wiring having the second stacked structure S2, the lower metal pattern included in the contact plug may be formed by the chemical vapor deposition process. The wiring having the second stacked structure S2 may include a metal material formed by the physical vapor deposition process.

In the wiring having the second stacked structure S2, the barrier metal pattern included in the contact plug may include, but is not limited to, titanium, titanium nitride, tantalum, tantalum nitride, tungsten nitride, tungsten nitride, or the like. The upper and lower metal patterns included in the wiring having the second stacked structure S2 may include a material that can be patterned by an etching process and have a low thermal budget in processes for forming a cell structure thereon. For example, the upper and lower metal patterns included in the wiring having the second stacked structure S2 may include tungsten or aluminum.

For example, in the wiring having the second stacked structure S2, the lower metal pattern included in the contact plug may include tungsten formed by the chemical vapor deposition process, and the upper metal pattern included in the conductive pattern may include tungsten formed by the physical vapor deposition.

In an example embodiment, in the wiring having the second stacked structure S2, the lower metal pattern included in the contact plug and the upper metal pattern included in the conductive pattern may include the same material. In this case, the lower metal pattern included in the contact plug and the upper metal pattern included in the conductive pattern may have different grain sizes because the lower metal patterns included in the contact plug and the upper metal pattern included in the conductive pattern are formed by different deposition processes. For example, in an example case in which the upper and lower metal patterns include tungsten, the tungsten included in the contact plug may have a grain size larger than a grain size of the tungsten included in the conductive pattern.

In an example embodiment, in the wiring having the second stacked structure S2, the lower metal pattern included in the contact plug and the upper metal pattern included in the conductive pattern may include different materials.

In an example case in which the wiring having the second stacked structure S2 and the wiring having the first stacked structure S1 include the same metal material (e.g., tungsten), the wiring having the second stacked structure S2 including the metal formed by the physical vapor deposition process may have a resistance lower than a resistance of the wiring having the first stacked structure S1 including the metal formed only by the chemical vapor deposition process. A multilayer interconnection structure may include the wiring having the second stacked structure S2, so that a total resistance of the multilayer interconnection structure may be reduced.

In an example embodiment, a third etch stop layer 170 may be provided on the fifth lower insulating interlayer 154 and the third wiring 164. For example, the third etch stop layer 170 may conformally cover surfaces of the fifth lower insulating interlayer 154 and the third wiring 164. A sixth lower insulating interlayer 172 and a seventh lower insulating interlayer 174 may be formed on the third etch stop layer 170. The sixth and seventh lower insulating interlayers 172 and 174 may have similar structures to the fourth and fifth lower insulating interlayers 152 and 154, respectively.

Fourth contact holes 176 may pass through the seventh lower insulating interlayer 174, and may expose an upper surface of the third wiring 164. A fourth wiring 184 may be provided on the seventh lower insulating interlayer 174 to fill the fourth contact hole 176.

The fourth wiring 184 may include a fourth contact plug C4 and a fourth conductive pattern. The fourth contact plug C4 may be provided in the fourth contact hole 176. For example, the fourth contact plug C4 may fill the fourth contact hole 176. The fourth conductive pattern L4 may be formed on the fourth contact plug C4 and the seventh lower insulating interlayer 174, and may be electrically connected to the fourth contact plug C4. The fourth conductive pattern L4 may extend in a direction parallel to the upper surface of the substrate 100.

The fourth wiring 184 may include a fourth barrier metal pattern 180a and a fifth metal pattern 182a provided on the fourth barrier metal pattern 180a. The fourth barrier metal pattern 180a may be formed along an inner surface of the fourth contact hole 176 and an upper surface of the seventh lower insulating interlayer 174. The fifth metal pattern 182a may be provided in the fourth contact hole 176. The fifth metal pattern 182a may fill the fourth contact hole 176. An upper surface of the fifth metal pattern 182a may be positioned over the seventh lower insulating interlayer 174. The fourth wiring 184 may have the first stacked structure S1.

The fourth wiring 184 may be an uppermost wiring of the lower wiring structure formed below the cell structure. Some of the conductive patterns (e.g., fourth conductive patterns) included in the uppermost wiring may serve as bit lines. The fourth conductive patterns L4 positioned in a memory cell region may serve as the bit lines. Hereinafter, the fourth conductive patterns L4 may also be referred to as the bit lines. The bit lines L4 may extend in the first direction. The bit lines L4 may be spaced apart from each other in the second direction.

In an example embodiment, a fourth etch stop layer pattern 190a may be provided on the seventh lower insulating interlayer 174 and the fourth wiring 184. For example, a fourth etch stop layer pattern 190a may conformally cover the surfaces of the seventh lower insulating interlayer 174 and the fourth wiring 184. An eighth lower insulating interlayer 192 may be formed on the fourth etch stop layer pattern 190a to fill the gap between the bit lines L4. An upper surface of the fourth etch stop layer pattern 190a on the bit line L4 and an upper surface of the eighth lower insulating interlayer 192 may be coplanar with each other. The fourth etch stop layer pattern 190a may include silicon nitride, and the eighth lower insulating interlayer 192 may include silicon oxide.

As described above, the lower wiring structure may include multi-layered wirings, and some of the conductive patterns included in the uppermost wiring may serve as the bit lines. At least one of the wiring included in the lower wiring structure may have the second stacked structure S2. At least one of the wiring included in the lower wiring structure may have the first stacked structure S1.

Since the wiring having the second stacked structure S2 has the resistance lower than the resistance of the wiring having the first stacked structure S1, the total resistance of the multilayer interconnection structure (e.g., the lower wiring structure) including the wiring having the second stacked structure S2 may be reduced. Since processes for forming the wiring having the second stacked structure S2 are more complicated than processes for forming of the wiring having the first stacked structure S1, the wiring having the second stacked structure S2 may be selectively provided in the multilayer interconnection structure.

In an example embodiment, as shown in FIG. 5, one of wirings provided below the uppermost wiring may have the second stacked structure S2. In FIG. 5, the third wiring 164 may have the second stacked structure S2, but it may not be limited thereto. For example, instead of the third wiring 164, the second wiring 144 or the first wiring 124 may have the second stacked structure S2.

A cell structure may be formed on the lower wiring structure. The cell structure may include a vertical channel transistor and a capacitor 246. The vertical channel transistor may include a channel pattern 214 and a word line pattern 218. In addition, the vertical channel transistor may include a mold insulation structure 204, a filling insulation structure 226, a landing pad 230, a fifth etch stop layer 234, and a plate electrode layer 248. Hereinafter, an example of the cell structure formed on the lower wiring structure may be described.

A first mold insulation pattern 200 and a second mold insulation pattern 202 may be stacked on the bit line L4 and the eighth lower insulating interlayer 192. Hereinafter, a structure in which the fourth etch stop layer pattern 190a, the first mold insulation pattern 200, and the second mold insulation pattern 202 are stacked may be referred to as a mold insulation structure 204.

The mold insulation structure 204 may have a line shape extending in the second direction. The mold insulation structure 204 may be provided to intersect the bit line L4. The plurality of mold insulation structures 204 may be spaced apart from each other in the first direction. Accordingly, a first trench 206 may be between the mold insulation structures 204. An upper surface of the bit line L4 may be exposed by a bottom of the first trench 206.

The first mold insulation pattern 200 may include silicon oxide and the second mold insulation pattern 202 may include silicon nitride. However, the disclosure is not limited thereto, and as such, the first mold insulation pattern and the second mold insulation pattern 202 may include materials other than silicon oxide or silicon nitride.

The channel pattern 214 may be conformally provided on a sidewall of the mold insulation structure 204 and the upper surface of the bit line L4 between the mold insulation structures 204. The channel pattern 214 may include two sidewalls extending in the vertical direction and a lower surface connecting lower portions of the two sidewalls facing each other in the first direction. The lower surface of the channel pattern 214 may contact the upper surface of the bit line L4. Accordingly, the channel pattern 214 may have U-shape in the cross-sectional view cut in the first direction. The channel patterns 214 may be regularly arranged in each of the first and second direction. The channel patterns 214 may be spaced apart from each other in the first direction and the second direction.

Hereinafter, a portion extending in the vertical direction of a U-shaped structure is referred to as a sidewall. Additionally, a horizontal portion connected to lower portions of both sidewalls referred to as a lower portion.

A bottom of the channel pattern 214 may contact the upper surface of the bit line L4. The mold insulation structure 204 may be provided between the channel patterns 214 in the first direction, and the channel patterns 214 may be aligned in the first direction. The channel patterns 214 may be spaced apart from each other in the second direction.

The channel pattern 214 may include an oxide semiconductor material. In an example embodiment, the channel pattern 214 may include InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO, or a combination thereof. For example, the channel pattern 214 may include InxGayZnzO. In an example embodiment, the channel pattern 214 may be amorphous state.

The gate insulation layer pattern 216 may be formed on an inner wall of the channel pattern 214 and a sidewall of the mold insulation structure 204. The gate insulation layer pattern 216 may extend in the second direction.

In an example embodiment, the gate insulation layer pattern 216 may not be formed on an inner lower surface of the channel pattern 214. In some an example embodiment, the gate insulation layer pattern 216 may be formed on an inner sidewall and the lower surface of the channel pattern 214, and thus the gate insulation layer pattern 216 may have U-shape in the cross-sectional view.

The gate insulation layer pattern 216 may include metal oxide having a dielectric constant higher than a dielectric constant of silicon nitride. The gate insulation layer pattern 216 may include, e.g., aluminum oxide, zirconium oxide, hafnium oxide, titanium oxide, or the like.

An uppermost surface of the gate insulation layer pattern 216 may be higher than an uppermost surface of the channel pattern 214. For example, as illustrated in FIG. 3, both ends of the gate insulation layer pattern 216 may be higher than an uppermost surface of the channel pattern 214. The uppermost surface of the gate insulation layer pattern 216 may be substantially coplanar with an upper surface of the mold insulation structure 204.

The word line pattern 218 may be provided on the inner sidewall of the gate insulation layer pattern 216. The word line pattern 218 may be provided on the both sidewalls of the channel pattern 214 having U-shape, respectively. Additionally, the word line pattern 218 may not be formed on the lower surface of the channel pattern 214 having U-shape. Each of the word line patterns 218 may extend in the second direction.

An uppermost surface of the word line pattern 218 may be lower than the upper surface of the mold insulation structure 204. Additionally, the uppermost surface of the word line pattern 218 may be lower than the uppermost surface of the gate insulation layer pattern 216.

The word line pattern 218 may include, but is not limited to, doped polysilicon, metal, conductive metal nitride, conductive metal silicide, conductive metal oxide, or a combination thereof. The plurality of word line patterns 218 may include, but is not limited to, doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOx, RuOx, or a combination thereof.

The word line pattern 218 may serve as a gate electrode of the vertical channel transistor. Each of the channel patterns 214 may serve as an active pattern. The gate insulation layer pattern 216 and the word line pattern 218 may be laterally stacked on each of the inner sidewalls of the channel pattern 214. The gate insulation layer pattern 216 may be interposed between the channel pattern 214 and the word line pattern 218. Accordingly, two vertical channel transistors connected in series may be provided on one channel pattern 214.

The filling insulation structure 226 may be formed on the word line pattern 218 to fill the first trench 206. An upper surface of the filling insulation structure 226 may be substantially coplanar with the upper surface of the mold insulation structure 204. The filling insulation structure 226 may have a line shape extending in the second direction. The filling insulation structure 226 may face the mold insulation structure 204 in the first direction.

In an example embodiment, the filling insulation structure 226 may include a liner insulation pattern 220, a first filling insulation pattern 222, and a second filling insulation pattern 224. The liner insulation pattern 220 may be formed conformally on the word line pattern 218, the lower surface of the channel pattern 214, and the surface of the gate insulation layer pattern 216 in the first trench 206. The first filling insulation pattern 222 may fill most of the first trench 206. The second filling insulation pattern 224 may fill an upper portion of the first trench 206. In an example embodiment, a bottom of the second filling insulation pattern 224 may be coplanar with or higher than an uppermost surface of the word line pattern 218. The liner insulation pattern 220 and the second filling insulation pattern 224 may include silicon nitride, and the first filling insulation pattern 222 may include silicon oxide. However, the disclosure is not limited thereto.

The gate insulation layer pattern 216 and the mold insulation structure 204 contacting the inner sidewall and an outer sidewall of the channel pattern 214 may protrude from the uppermost surface of the channel pattern 214. Therefore, a recess 228 may form between the gate insulation layer pattern 216 and the mold insulation structure 204 contacting the inner sidewall and the outer sidewall of the channel pattern 214. The channel pattern 214 may be exposed by a bottom of the recess 228.

The landing pad 230 may fill the recess 228. An upper surface of the landing pad 230 may protrude from the upper surfaces of the mold insulation structure 204 and the filling insulation structure 226. The landing pads 230 may contact the uppermost surfaces of the channel patterns 214, respectively. The landing pads 230 may include a conductive material. The landing pads 230 may have a circular, oval, rectangular, square, diamond, or hexagonal shape, in a plan view.

An upper insulation pattern 232 may fill a gap between the landing pads 230. The upper insulation pattern 232 may include silicon nitride, but is not limited thereto.

The fifth etch stop layer 234 may be formed on the landing pads 230 and the upper insulation pattern 232. The capacitors 246 may pass through the fifth etch stop layer 234, and may contact the upper surfaces of the landing pads 230, respectively. Each of the capacitor 246 may include a lower electrode 240, a dielectric layer 242, and an upper electrode 244.

In an example embodiment, a support layer pattern (not shown) connecting sidewalls of the lower electrodes 240 may be further included.

The plate electrode layer 248 may be formed on the upper electrode 244. The plate electrode layer 248 may include silicon germanium, but is not limited thereto.

The capacitor 246 and the plate electrode layer 248 may be formed only on the memory cell region. An upper insulating interlayer 250 may cover the plate electrode layer 248 and the upper insulation pattern 232.

As described above, the lower wiring structure may include at least one of the wirings having the first stacked structure S1 and at least one of the wirings having the second stacked structure S2.

The lower wiring structure included in the semiconductor device may have various structures including at least one of the wirings having the first stacked structure S1 and at least one of the wirings having the second stacked structure S2. Hereinafter, examples of the lower wiring structures may be described.

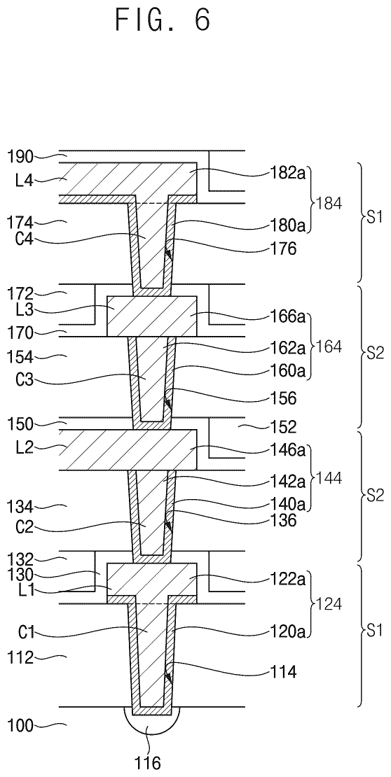

FIG. 6 is an enlarged cross-sectional view of a lower wiring structure in a semiconductor device according to an example embodiment.

Referring to FIG. 6, the lower wiring structure may include the first to fourth wirings 124, 144, 164, and 184 stacked in the vertical direction. According to an example embodiment in FIG. 6, at least two of the wirings in the lower wiring structure may have the second stacked structure S2.

For example, the second and third wirings 144 and 164 may have the second stacked structure S2.

The second wiring 144 may include the second contact plug C2 including the barrier metal pattern 140a and the lower metal pattern 142a, and the second conductive pattern L2 including the upper metal pattern 146a. The third wiring 164 may include the third contact plug C3 including the barrier metal pattern 160a and the lower metal pattern 162a, and the third conductive pattern L3 including the upper metal pattern 166a.

In each of the second and third wirings 144 and 164, the barrier metal pattern may be formed only inside the contact hole. For example, in each of the second and third wirings 144 and 164, the upper surface of the barrier metal pattern may not be provided above the contact hole. That is, in each of the second and third wirings 144 and 164, the barrier metal pattern may be formed only on an inner surface of the contact hole, and a connection portion between the contact plug and the conductive pattern may be distinguished. For example, the contact plug and the conductive pattern may be independent and/or distinct from each other. For example, the contact plug and the conductive pattern may be formed as a two-piece structure. Additionally, the conductive pattern may have a resistance lower than a resistance of the contact plug.

The semiconductor device may have the cell structure as described with reference to FIGS. 3 and 4 on the lower wiring structure.

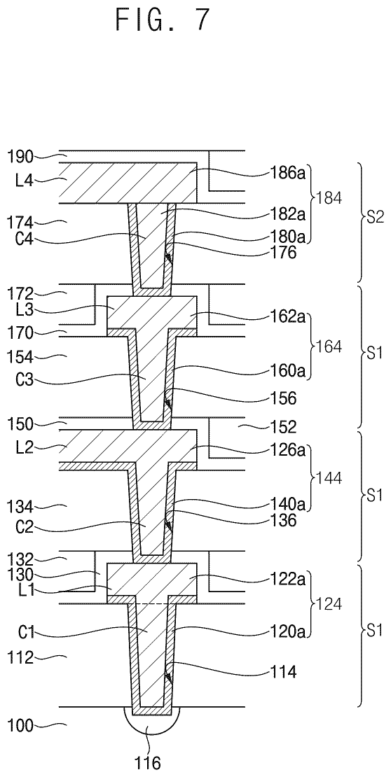

FIG. 7 is an enlarged cross-sectional view of a lower wiring structure in a semiconductor device according to an example embodiment.

Referring to FIG. 7, the lower wiring structure may include the first to fourth wirings 124, 144, 164, and 184 stacked in the vertical direction. In the lower wiring structure, an uppermost wiring including the bit line L4 may have the second stacked structure S2. The first to third wirings 124, 144, and 164 positioned below the uppermost wiring may have the first stacked structure S1.

As shown in FIG. 7, the fourth wiring 184 may have the second stacked structure S2. The fourth wiring 184 may include the fourth contact plug C5 including the barrier metal pattern 180a and the lower metal pattern 182a, and the fourth conductive pattern L4 including the upper metal pattern 186a.

The semiconductor device may have the cell structure as described with reference to FIGS. 3 and 4 on the lower wiring structure.

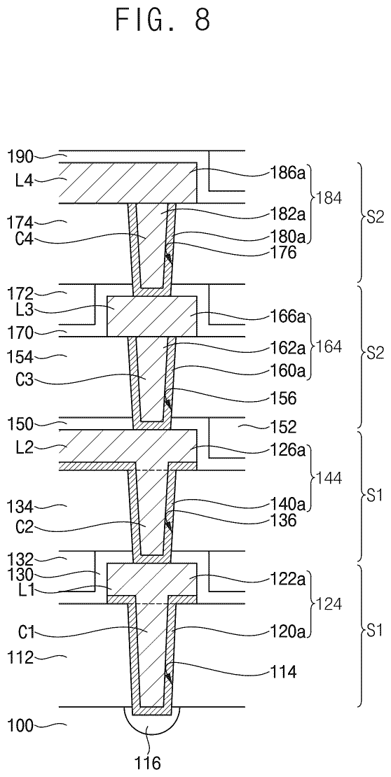

FIG. 8 is an enlarged cross-sectional view of a lower wiring structure in a semiconductor device according to an example embodiment.

Referring to FIG. 8, the lower wiring structure may include the first to fourth wirings 124, 144, 164, and 184 stacked in the vertical direction. In the lower wiring structure, the uppermost wiring including the bit line L4 may have the second stacked structure S2. In the lower wiring structure, a lowermost first wiring 124 may have the first stacked structure S1. Moreover, at least one of the second to third wirings 144 and 164 positioned between an uppermost wiring and the lowermost wiring may have the second stacked structure S2.

For example, as shown in FIG. 8, the third and fourth wirings 164 and 184 may have the second stacked structure S2.

The third wiring 164 may include the third contact plug C3 including the barrier metal pattern 160a and the lower metal pattern 162a, and the third conductive pattern L3 including the upper metal pattern 166a. The fourth wiring 184 may have the second stacked structure S2. The fourth wiring 184 may include the fourth contact plug C5 including the barrier metal pattern 180a and the lower metal pattern 182a, and the second conductive pattern L4 including the upper metal pattern 186a.

The semiconductor device may have the cell structure as described with reference to FIGS. 3 and 4 on the lower wiring structure.

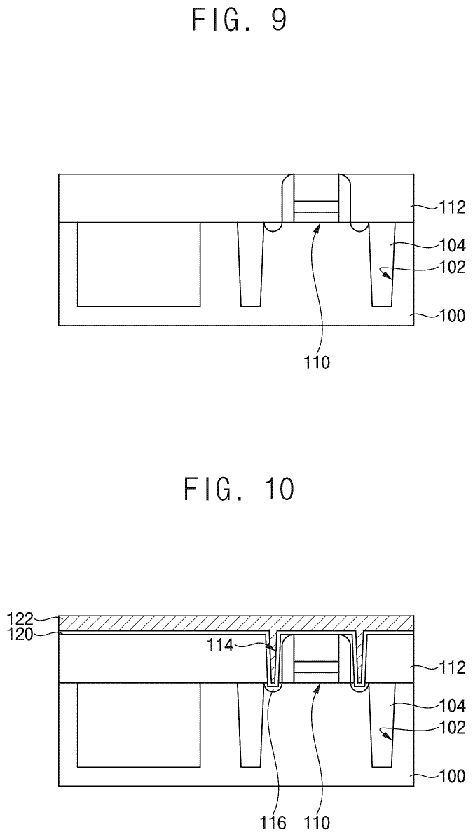

FIGS. 9 to 27 are cross-sectional views of stages in a method of manufacturing a semiconductor device according to an example embodiment.

FIGS. 9 to 27 are cross-sectional views are taken along line A-A′ of FIG. 4.

Referring to FIG. 9, a trench isolation process may be performed on a substrate 100 to form an isolation pattern 104 in the trench 102 at an upper portion of the substrate 100. Additionally, peripheral transistors 110 constituting peripheral circuits may be formed on the substrate 100. Although only one peripheral transistor is shown in FIG. 9, a plurality of peripheral transistors may be formed on the substrate 100.

The peripheral transistors 110 may serve as a peripheral circuit structure including core circuits and peripheral circuits. Each of the peripheral transistors 110 may be a planar type transistor.

A first lower insulating interlayer 112 may be formed on the substrate 100 to cover the peripheral transistors 110. The first lower insulating interlayer 112 may include silicon oxide, but is not limited thereto.

Referring to FIG. 10, the first lower insulating interlayer 112 may be etched to form first contact holes 114 passing through the first lower insulating interlayer 112 and exposing a surface of the substrate 100.

In an example embodiment, a metal silicide pattern 116 may be formed on the substrate 100 exposed by a bottom of each of the first contact holes 114.

A first barrier metal layer 120 may be provided on surfaces of the first contact holes 114 and the first lower insulating interlayer 112. For example, the first barrier metal layer 120 may be formed on surfaces of the first contact holes 114 and the first lower insulating interlayer 112. That is, the first barrier metal layer 120 may be formed to conform to the surfaces of the first contact holes 114 and the first lower insulating interlayer 112. A first metal layer 122 may be formed on the first barrier metal layer 120 to fill the first contact hole 114.

In an example embodiment, the first barrier metal layer 120 and the first metal layer 122 may be formed by a chemical vapor deposition process. The first barrier metal layer 120 may include, but is not limited to, titanium, titanium nitride, tantalum, tantalum nitride, tungsten nitride, tungsten carbon nitride, etc. The first metal layer 122 may include, but is not limited to, tungsten.

A metal layer formed by the chemical vapor deposition process may have a gap filling characteristic superior to a metal layer formed by a physical vapor deposition process. Therefore, in an example case in which the first metal layer 122 is formed by the chemical vapor deposition process, the first metal layer 122 may be formed in the first contact hole 114 without void.

In an example case in which the metal layer is formed by the chemical vapor deposition process, the metal layer may have a poor adhesion characteristic between the metal layer and an insulation layer. Therefore, the first barrier metal layer 120 may be interposed between the first metal layer 122 and the first lower insulating interlayer 112. The first barrier metal layer 120 may be an adhesion layer for the first metal layer 122.

Referring to FIG. 11, the first metal layer 122 and the first barrier metal layer 120 may be etched to form a first wiring 124 including the first barrier metal pattern 120a and the first metal pattern 122a. The first wiring 124 may be formed on the first lower insulating interlayer 112. For example, the first wiring 124 may be formed on the first lower insulating interlayer 112 and may fill the first contact holes 114. The first wiring 124 may include a first contact plug C1 filling the first contact hole 114, and a first conductive pattern L1 on the first contact plug C1 and the first lower insulating interlayer 112. The first conductive pattern L1 may be electrically connected to the first contact plug C, and may extend in a direction parallel an upper surface of the substrate 100.

The first wiring 124 may be a lowermost wiring directly connected to the substrate 100. In the first wiring 124, the first barrier metal pattern 120a may be provided on a sidewall and a bottom of the first contact hole 114, and an upper surface of the first lower insulating interlayer 112. For example, the first barrier metal pattern 120a may be formed to conform to the sidewall and the bottom of the first contact hole 114, and the upper surface of the first lower insulating interlayer 112. The first metal pattern 122a may be formed to fill the first contact hole 114 on the first barrier metal pattern 120a.

The first metal pattern 122a may contact an entire upper surface of the first barrier metal pattern 120a. However, the disclosure is not limited thereto, and as such, the first metal pattern 122a may contact partially contact an upper surface of the first barrier metal pattern 120a. Moreover, since the first contact plug C1 and the first conductive pattern L1 include the first metal pattern 122a having one body, a connection portion (e.g., an interface) between the first contact plug C1 and the first conductive pattern L1 may not be distinguished. For example, the first contact plug C1 and the first conductive pattern L1 may be provided as an one-piece (or a single piece) structure. According to an embodiment, the first contact plug C1 and the first conductive pattern L1 may not have a distinct interface therebetween. The first wiring 124, which is the lowermost wiring directly contacting the substrate 100, may have the first stacked structure S1.

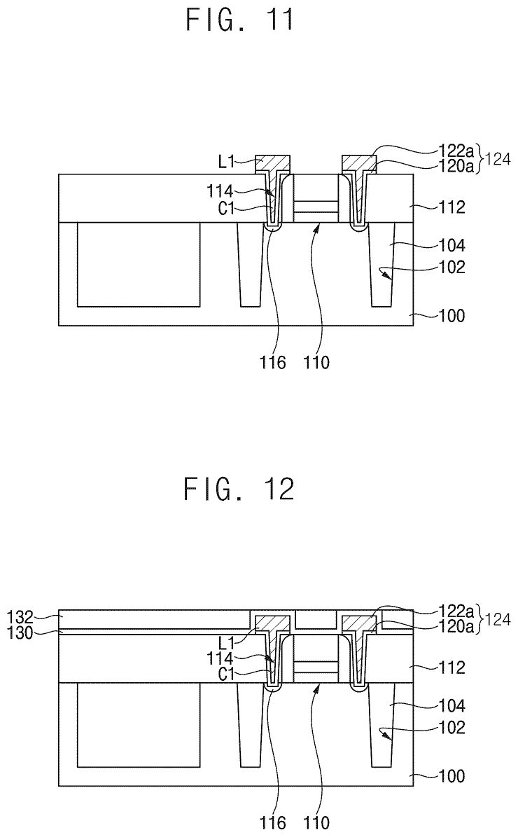

Referring to FIG. 12, a first etch stop layer 130 may be provided on the surfaces of the first lower insulating interlayer 112 and the first wiring 124. The first etch stop layer 130 may be conformally formed on the surfaces of the first lower insulating interlayer 112 and the first wiring 124. The first etch stop layer 130 may include, but is not limited to, silicon nitride.

A second lower insulating interlayer 132 may be formed on the first etch stop layer 130. The second lower insulating interlayer 132 may be planarized until an upper surface of the first etch stop layer 130 is exposed. The second lower insulating interlayer 132 may include, but is not limited to, silicon oxide.

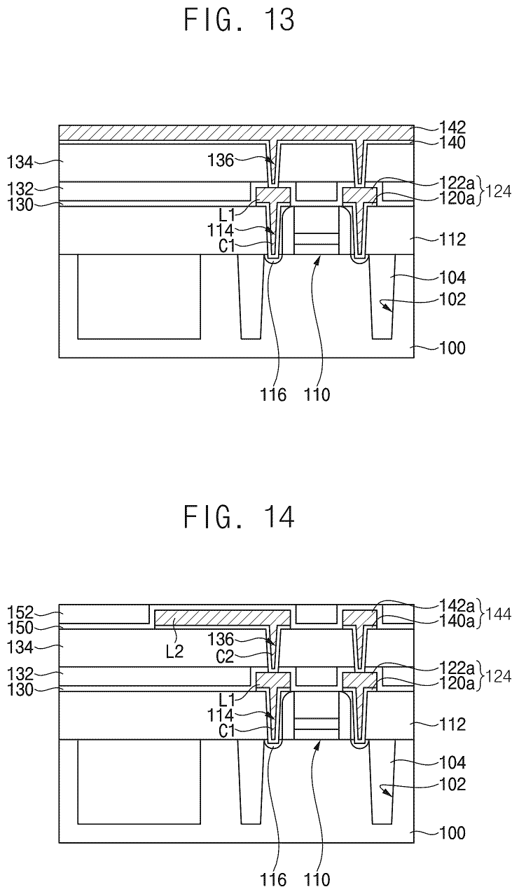

Referring to FIG. 13, a third lower insulating interlayer 134 may be formed on the second lower insulating interlayer 132 and the first etch stop layer 130.

The third lower insulating interlayer 134 and the first etch stop layer 130 may be etched to form second contact holes 136 passing through the third lower insulating interlayer 134 and the first etch stop layer 130 and exposing an upper surface of the first metal pattern.

A second barrier metal layer 140 may be provided on the surface of the second contact hole 136 and the third lower insulating interlayer 134. The second barrier metal layer 140 may be conformally formed on the surface of the second contact hole 136 and the third lower insulating interlayer 134. A second metal layer 142 may be formed on the second barrier metal layer 140 to fill the second contact hole 136.

In an example embodiment, the second barrier metal layer 140 and the second metal layer 142 may be formed by the chemical vapor deposition process. The second barrier metal layer 140 may include, but is not limited to, titanium, titanium nitride, tantalum, tantalum nitride, tungsten nitride, tungsten carbon nitride, etc. The second metal layer 142 may include, but is not limited to, tungsten.

The third lower insulating interlayer 134 may include, but is not limited to, silicon nitride or silicon oxide. In an example embodiment, lower insulating interlayers provided above the lowermost wiring and including contact holes may include silicon nitride.

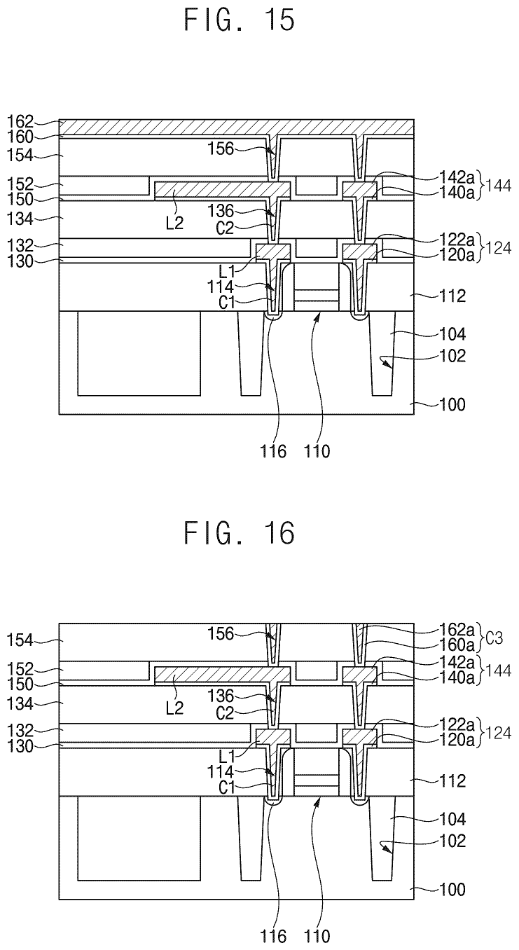

Referring to FIG. 14, the second metal layer 142 and the second barrier metal layer 140 are etched to form a second wiring 144 including a second barrier metal pattern 140a and a second metal pattern 142a. The second wiring 144 may be formed on the third lower insulating interlayer 134 to fill the second contact holes 136. The second wiring 144 may include a second contact plug C2 filling the second contact hole 136, and the second conductive pattern L2 provided on the second contact plug C2 and the third lower insulating interlayer 134. The second conductive pattern L2 may be electrically connected to the second contact plug C2, and may extend in a direction parallel to an upper surface of the substrate 100.

The second wiring 144 may have the first stacked structure S1.

A second etch stop layer 150 may be provided on surfaces of the third lower insulating interlayer 134 and the second wiring 144. The second etch stop layer 150 may be conformally formed on surfaces of the third lower insulating interlayer 134 and the second wiring 144. The second etch stop layer 150 may include, but is not limited to, silicon nitride.

A fourth lower insulating interlayer 152 may be formed on the second etch stop layer 150. The fourth lower insulating interlayer 152 may be planarized until an upper surface of the second etch stop layer 150 is exposed. The fourth lower insulating interlayer 152 may include, but is not limited to, silicon oxide.

Referring to FIG. 15, a fifth lower insulating interlayer 154 may be formed on the fourth lower insulating interlayer 152 and the second etch stop layer 150.

The fifth lower insulating interlayer 154 and the second etch stop layer 150 may be etched to form third contact holes 156 passing through the fifth lower insulating interlayer 154 and the second etch stop layer 150 and exposing the upper surface of the second metal pattern 142a.

A third barrier metal layer 160 may be conformally formed on surfaces of the third contact hole 156 and the fifth lower insulating interlayer 154. The third barrier metal layer 160 may be conformally formed on surfaces of the third contact hole 156 and the fifth lower insulating interlayer 154. A third metal layer 162 may be formed on the third barrier metal layer 160 to fill the third contact hole 156.

In an example embodiment, the third barrier metal layer 160 and the third metal layer 162 may be formed by the chemical vapor deposition process. The third barrier metal layer 160 may include, but is not limited to, titanium, titanium nitride, tantalum, tantalum nitride, tungsten nitride, tungsten carbon nitride, etc. The third metal layer 162 may include, but is not limited to, tungsten.

The fifth lower insulating interlayer 154 may include, but is not limited to, silicon nitride or silicon oxide. In an example embodiment, the fifth lower insulating interlayer 154 may include silicon nitride.

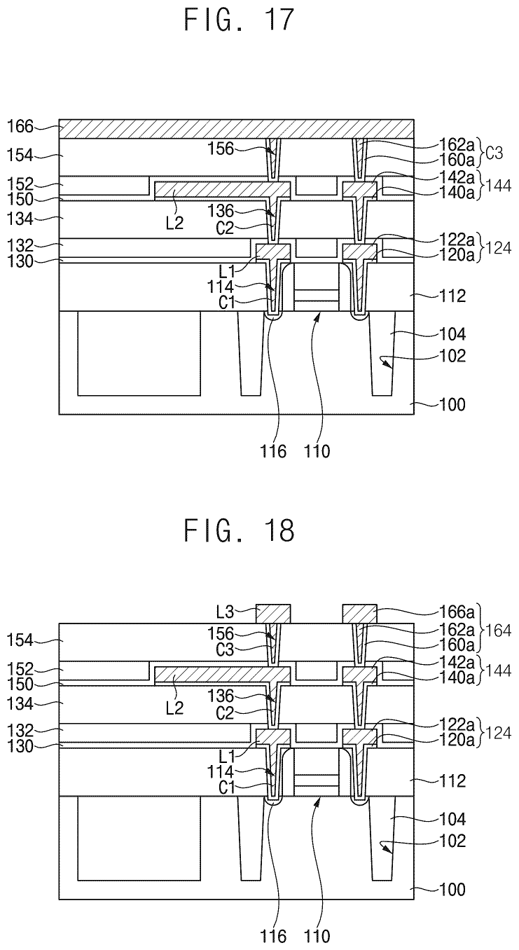

Referring to FIG. 16, the third metal layer 162 and the third barrier metal layer 160 may be planarized until an upper surface of the fifth lower insulating interlayer 154 is exposed to form a third barrier metal pattern 160a and a third metal pattern 162a. The third barrier metal pattern 160a and the third metal pattern 162a may fill the third contact hole 156, and may serve as a third contact plug C3.

The third contact plug C3 may include a metal material formed by the chemical vapor deposition process. For example, the third contact plug C3 may include tungsten formed by the chemical vapor deposition process.

Referring to FIG. 17, a fourth metal layer 166 may be formed on the fifth lower insulating interlayer 154 and the third contact plug C3.

In an example embodiment, the fourth metal layer 166 may be formed by a physical vapor deposition process. A metal layer formed by the physical vapor deposition process may have a poor gap filling characteristic and a poor step coverage characteristic compared to a metal layer formed by the chemical vapor deposition process. Therefore, if the metal layer is formed to fill the contact hole by the physical vapor deposition process, the metal layer may include void. However, since upper surfaces of the fifth lower insulating interlayer 154 and the third contact plug C3 are substantially flat, the fourth metal layer 166 formed by the physical vapor deposition process may have no void.

In an example case in which the fourth metal layer 166 is formed by the physical vapor deposition process, the fourth metal layer 166 may have excellent adhesion between the fifth lower insulating interlayer 154 and the fourth metal layer 166 so that barrier metal layer may not be formed. Therefore, the fourth metal layer 166 may directly contact the fifth lower insulating interlayer 154. For example, the fourth metal layer 166 may include tungsten formed by the physical vapor deposition process.

Referring to FIG. 18, the fourth metal layer 166 may be etched to form a fourth metal pattern 166a on the fifth lower insulating interlayer 154 and the third contact plug C3. The fourth metal pattern 166a may have a line shape extending in a direction parallel to an upper surface of the substrate 100.

A metal layer formed by the physical vapor deposition process may have a metal purity higher than a metal purity of a metal layer formed by the chemical vapor deposition process. Therefore, the metal layer formed by the physical vapor deposition process may have a resistance lower than a resistance of the metal layer formed by the chemical vapor deposition process. In an example embodiment, the fourth metal pattern 166a may have a resistance lower than a resistance of the third metal pattern 162a.

In an example embodiment, the fourth metal pattern 166a may include a material the same as a material of the third metal pattern 162a. In this case, since the fourth metal pattern 166a and the third metal pattern 162a are formed by different deposition processes, the materials of the third and fourth metal patterns 162a and 166a may have different grain sizes. In an example embodiment, the fourth metal pattern 166a may have a grain size smaller than a grain size of the third metal pattern 162a.

In some an example embodiment, the fourth metal pattern 166a may include a material different from a material of the third metal pattern 162a, and a resistance of the material included in the fourth metal pattern 166a may be lower than a resistance of the material included in the third metal pattern 162a.

As described above, a third wiring 164 including the third contact plug C3 and the third conductive pattern L3 may be formed on the second wiring 144. The third contact plug C3 may include the third barrier metal pattern 160a and the third metal pattern 162a, and the third conductive pattern L3 may include the fourth metal pattern 166a.

In the third wiring 164, the third barrier metal pattern 160a may be formed only on a sidewall and a bottom of the third contact hole 156. The third barrier metal pattern 160a may not be formed on an upper surface of the fifth lower insulating interlayer 154. In addition, the third metal pattern 162a included in the third contact plug C3 and the fourth metal pattern 166a included in the third conductive pattern L3 may be formed by different deposition processes, so that an interface between the third metal pattern 162a and the fourth metal pattern 166a may be generated. An interface between the third and fourth metal patterns 162a and 166a may be distinguished. For example, the third and fourth metal patterns 162a and 166a may be independent and/or distinct from each other. For example, the third and fourth metal patterns 162a and 166a may be formed as a two-piece structure.

The third wiring 164 may have the second stacked structure S2. The conductive pattern included in the second stacked structure S2 may be formed by the physical vapor deposition process. Accordingly, the wiring having the second stacked structure S2 may have a resistance lower than a resistance of the wiring having the first stacked structure S1.

Referring to FIG. 19, a third etch stop layer 170 may be provided on the surfaces of the fifth lower insulating interlayer 154 and the third wiring 164. The third etch stop layer 170 may be conformally formed on the surfaces of the fifth lower insulating interlayer 154 and the third wiring 164. The third etch stop layer 170 may include, but is not limited to, silicon nitride.

A sixth lower insulating interlayer 172 may be formed on the third etch stop layer 170. The sixth lower insulating interlayer 172 may be planarized until an upper surface of the third etch stop layer 170 is exposed. The sixth lower insulating interlayer 172 may include, but is not limited to, silicon oxide.

A seventh lower insulating interlayer 174 may be formed on the sixth lower insulating interlayer 172 and the third etch stop layer 170.

The seventh lower insulating interlayer 174 and the third etch stop layer 170 may be etched to form fourth contact holes 176 passing through the seventh lower insulating interlayer 174 and the third etch stop layer 170 and exposing an upper surface of the fourth metal pattern 166a.

A fourth barrier metal layer 180 may be provided on surfaces of the fourth contact hole 176 and the seventh lower insulating interlayer 174. The fourth barrier metal layer 180 may be conformally formed on surfaces of the fourth contact hole 176 and the seventh lower insulating interlayer 174. A fifth metal layer 182 may be formed on the fourth barrier metal layer 180 to fill the fourth contact hole 176.

In an example embodiment, the fourth barrier metal layer 180 and the fifth metal layer 182 may be formed by the chemical vapor deposition process. The fourth barrier metal layer 180 may include, but is not limited to, titanium, titanium nitride, tantalum, tantalum nitride, tungsten nitride, tungsten carbon nitride, or the like. The fifth metal layer 182 may include, but is not limited to, tungsten.

The seventh lower insulating interlayer 174 may include, but is not limited to, silicon nitride or silicon oxide. In an example embodiment, the seventh lower insulating interlayer 174 may include silicon nitride.

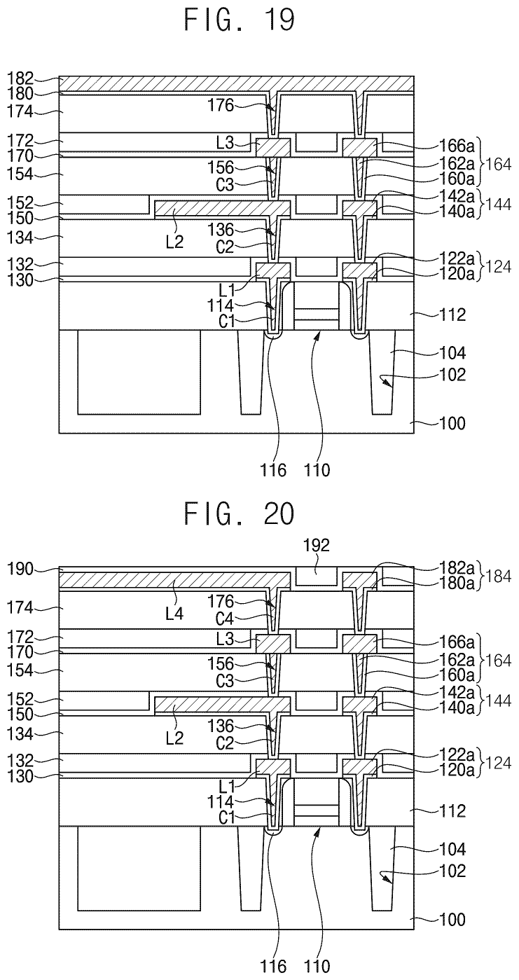

Referring to FIG. 20, the fifth metal layer 182 and the fourth barrier metal layer 180 may be etched to form a fourth wiring 184 including a fourth barrier metal pattern 180a and a fifth metal pattern 182a. The fourth wiring 184 may be formed on the seventh insulating interlayer 174 to fill the fourth contact holes 176. The fourth wiring 184 may include a fourth contact plug C4 filling the fourth contact hole 176 and a fourth conductive pattern L4 provided on the fourth contact plug C4 and the seventh lower insulating interlayer 174. The fourth conductive pattern L4 may be connected to the fourth contact plug C4. The fourth wiring 184 may have the first stacked structure S1.

The fourth wiring 184 may be an uppermost wiring, and may serve as a bit line L4. The bit line L4 may extend in the first direction.

As described above, the lower wiring structure may include the third wiring 164 having the second stacked structure S2, and the first, second, and fourth wirings 124, 144, and 184 having the first stacked structure S1.

In an example embodiment, the lower wiring structure of various structures including at least one of the first to fourth wirings 124, 144, 164, and 184 having the first stacked structure S1, and at least one of the first to fourth wirings 124, 144, 164 and 184 having the second stacked structure S2 may be manufactured. For example, the wiring having the second stacked structure may be formed by performing processes the same as described with reference to FIGS. 15 to 18. The wiring having the first stacked structure may be formed by performing the processes the same as described with reference to FIGS. 13 and 14.

A fourth etch stop layer 190 may be provided on surfaces of the seventh lower insulating interlayer 174 and the fourth wiring 184. The fourth etch stop layer 190 may be conformally formed on surfaces of the seventh lower insulating interlayer 174 and the fourth wiring 184. The fourth etch stop layer 190 may include, but is not limited to, silicon nitride.

An eighth lower insulating interlayer 192 may be formed on the fourth etch stop layer 190. The eighth lower insulating interlayer 192 may be planarized until an upper surface of the fourth etch stop layer 190 is exposed. The eighth lower insulating interlayer 192 may include, but is not limited to, silicon oxide.

As described above, the lower wiring structure including the wirings 124, 144, 164, and 184 may be formed on the substrate 100, and the uppermost wiring in the lower wiring structure may be a bit line L4.

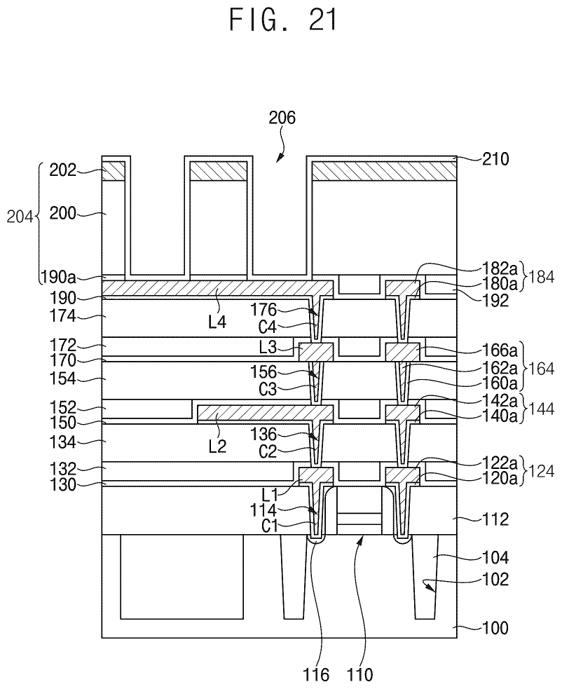

Referring to FIG. 21, a first mold insulation layer and a second mold insulation layer may be sequentially formed on the fourth etch stop layer 190 and the eighth lower insulating interlayer 192.

The second mold insulation layer, the first mold insulation layer, and the fourth etch stop layer 190 may be patterned to form a mold insulation structure 204. The mold insulation structure 204 may have a structure in which a fourth etch stop layer pattern 190a, a first mold insulation pattern 200, and a second mold insulation pattern 202 are stacked.

The first mold insulation pattern 200 may include, but is not limited to, silicon oxide. The second mold insulation pattern 202 may include, but is not limited to, silicon nitride.

The mold insulation structures 204 may have a line shape extending in the second direction. The mold insulation structures 204 may be spaced apart from each other in the first direction. A first trench 206 extending in the second direction may be formed between the mold insulation structures 204. The fourth conductive pattern L4 and the eighth lower insulating interlayer 192 may be exposed by a bottom of the first trench 206. Therefore, the bit line L4 may be exposed by a bottom of the first trench 206.

A channel layer 210 may be provided on the surface of the mold insulation structure 204 and the bottom of the first trench 206. The channel layer 210 may be conformally formed on the surface of the mold insulation structure 204 and the bottom of the first trench 206. The channel layer 210 may include an oxide semiconductor. The channel layer 210 including the oxide semiconductor may serve as a channel pattern for a vertical channel transistor by subsequent processes.

The channel layer 210 may cover the surface of the mold insulation structure 204, an upper surface of the fourth conductive pattern L4, and an upper surface of the eighth lower insulating interlayer 192. The channel layer 210 may not completely fill the first trench 206, and may be formed to have a uniform thickness along a surface profile of the first trench 206. The channel layer 210 may contact the fourth conductive pattern L4.

In an example embodiment, the channel layer 210 may be amorphous state. The channel layer 210 may include, but is not limited to, InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO, or a combination thereof. For example, the channel layer 210 may include InxGayZnzO.

In an example embodiment, the channel layer 210 may be formed by an atomic layer deposition process.

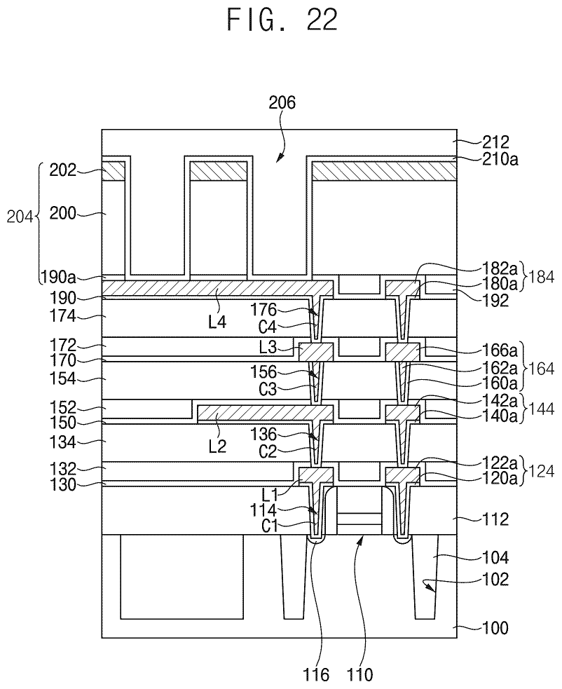

Referring to FIG. 22, a first sacrificial layer may be formed on the channel layer

210. The first sacrificial layer may fill the first trench 206. An upper surface of the first sacrificial layer may be substantially flat. In an example embodiment, the first sacrificial layer may include a spin-on hard mask. The spin-on hard mask may include, but is not limited to, amorphous carbon.

A first etch mask may be formed on the first sacrificial layer. The first sacrificial layer may be anisotropically etched using the first etch mask to form a first sacrificial layer pattern 212. Subsequently, the channel layer 210 may be anisotropically etched using the first sacrificial layer pattern 212 as an etch mask to form a preliminary channel pattern 210a. Accordingly, the preliminary channel patterns 210a may be separated to each other in the second direction, and may be spaced apart from each other in the second direction.

The first etch mask may overlap the upper surface of the bit line L4. Accordingly, the first sacrificial layer pattern 212 may extend in the first direction to cover the upper surface of the bit line L4. A first opening may be formed between the first sacrificial layer patterns 212 and the mold insulation structures 204.

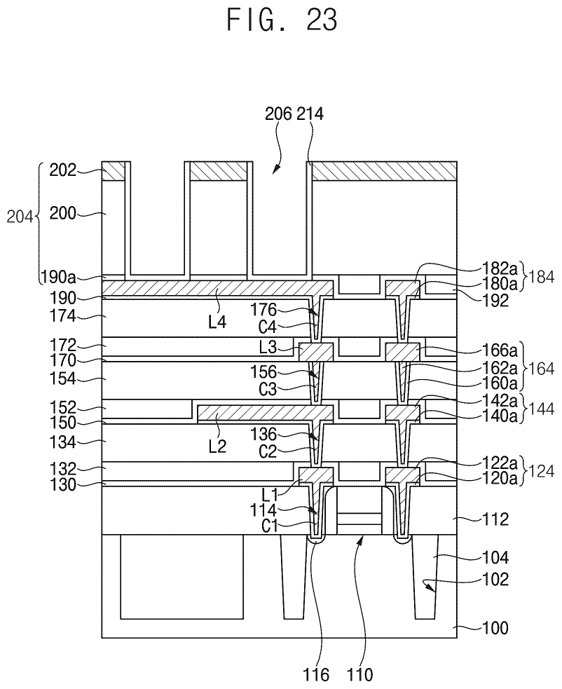

Referring to FIG. 23, a second sacrificial layer may be formed on the eighth lower insulating interlayer 192, the mold insulation structure 204, the first sacrificial layer pattern 212, and the preliminary channel pattern 210a to fill the first opening.

The second sacrificial layer, the first sacrificial layer pattern 212, and the preliminary channel pattern 210a may be planarized until an upper surface of the mold insulation structure 204 is exposed. Accordingly, nodes of the preliminary channel pattern 210a may be separated to form a plurality of channel patterns 214. The planarization process may include an etch-back process.

Each of the channel patterns 214 may be provided on a sidewall of the mold insulation structure 204 and the upper surface of the bit line L4 between the mold insulation structures 204. For example, each of the channel patterns 214 may be conformally formed on a sidewall of the mold insulation structure 204 and the upper surface of the bit line L4 between the mold insulation structures 204. Each of the channel patterns 214 may have U-shape, in the cross-sectional view. The channel patterns 214 may be spaced apart in the each of the first and second directions. A bottom of each of the channel patterns 214 may contact the bit line L4.

The mold insulation structure 204 may be provided between the channel patterns 214 in the first direction, and the channel patterns 214 may be aligned in the first direction. The eighth lower insulating interlayer 192 may be exposed between the channel patterns 214 in the second direction.

Thereafter, the first sacrificial layer pattern 212 and the second sacrificial layer may be removed. The removing of the first sacrificial layer pattern 212 and the second sacrificial layer may include an ashing process and a cleaning process. Accordingly, the upper surface of the channel pattern 214 may be exposed. Further, the first trench 206 may be formed again between the mold insulation structures 204.

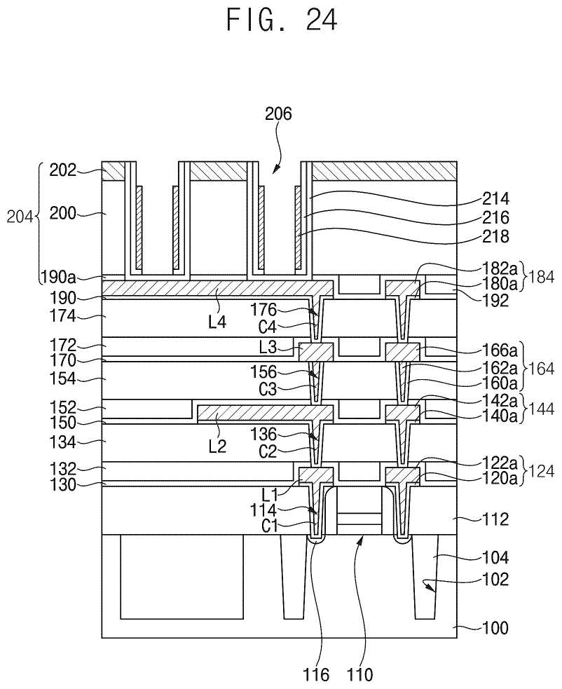

Referring to FIG. 24, a gate insulation layer and a fifth conductive layer may be formed on the channel pattern 214, the mold insulation structure 204, and the eighth lower insulating interlayer 192.

The gate insulation layer and the fifth conductive layer may be provided on the channel pattern 214, the mold insulation structure 204, and the eighth lower insulating interlayer 192. For example, the gate insulation layer and the fifth conductive layer may be conformally formed on the surfaces of the channel pattern 214, mold insulation structure 204, and eighth lower insulating interlayer 192.

In an example embodiment, the gate insulation layer may include a metal oxide having a dielectric constant higher than a dielectric constant of silicon nitride. For example, the gate insulation layer may include aluminum oxide. The fifth conductive layer may include metal or metal nitride, e.g., titanium nitride.

In an example embodiment, the gate insulation layer and the fifth conductive layer may be formed by the atomic layer deposition process.

The fifth conductive layer and the gate insulation layer formed between the upper surface of the mold insulation structure 204 and the mold insulation structure 204 may be anisotropically etched. Accordingly, the fifth conductive layer and the gate insulation layer may be separated from each other to form a word line pattern 218 and a gate insulation layer pattern 216, respectively.

The gate insulation layer pattern 216 and the word line pattern 218 may be formed on the sidewall of the mold insulation structure 204, and may extend in the second direction. The channel pattern 214, the gate insulation layer pattern 216, and the word line pattern 218 may be sequentially stacked on the sidewall of the mold insulation structure 204. The word line pattern 218 may serve as a gate electrode of the vertical channel transistor. An upper surface of the word line pattern 218 may be lower than the upper surface of the mold insulation structure 204.

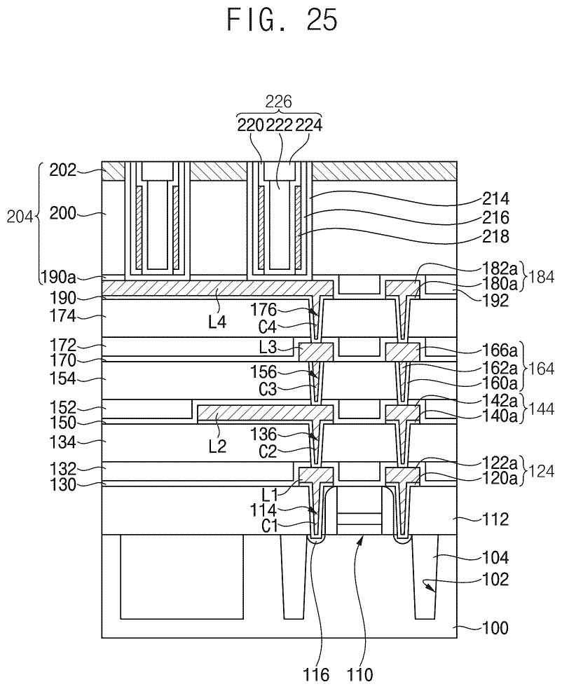

Referring to FIG. 25, a filling insulation structure 226 may be formed to fill the inside of the first trench 206. The filling insulation structure 226 may include a liner insulation pattern 220 and first and second filling insulation patterns 222 and 224.

The liner insulation pattern 220 may be provided on the word line pattern 218, the gate insulation layer pattern 216, and the channel pattern 214 in the first trench 206. For example, the liner insulation pattern 220 may be conformally formed on surfaces of the word line pattern 218, the gate insulation layer pattern 216, and the channel pattern 214 in the first trench 206. The first and second filling insulation patterns 222 and 224 may be formed on the liner insulation pattern 220.

An upper surface of the filling insulation structure 226 may be substantially coplanar with the upper surface of the mold insulation structure 204.

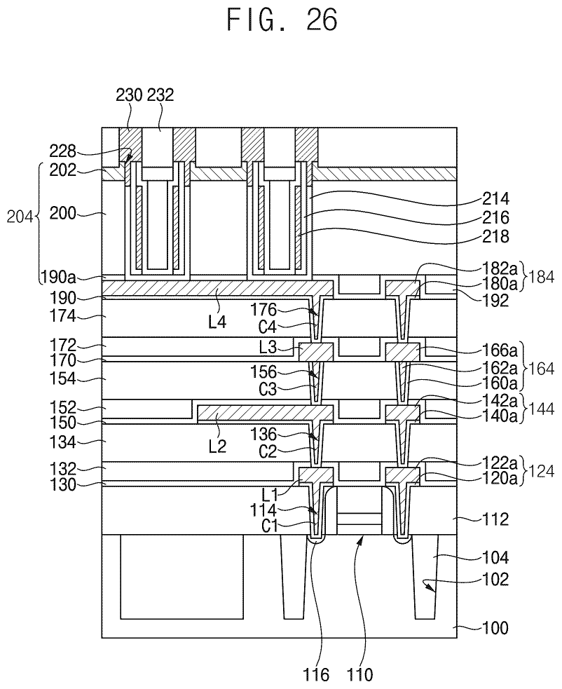

Referring to FIG. 26, an upper portion of the channel patterns 214 may be partially etched to form a recess 228.

The recess 228 may be formed between the gate insulation layer pattern 216 and the mold insulation structure 204 provided on the both sidewalls of the channel patterns 214. The channel pattern 214 may be exposed by a bottom of the recess 228. The uppermost surface of the channel pattern 214 may be lower than the upper surface of the mold insulation structure 204.

A sixth conductive layer may be formed to fill the recess 228. The sixth conductive layer may be patterned to form landing pads 230 contacting the upper surfaces of the channel patterns 214, respectively. Each of the landing pads 230 may have a circular, oval, rectangular, square, diamond, or hexagonal, in a plan view.

An upper insulation pattern 232 may be formed to fill a space between the landing pads 230. The upper insulation pattern 232 may include, but is not limited to, silicon nitride.

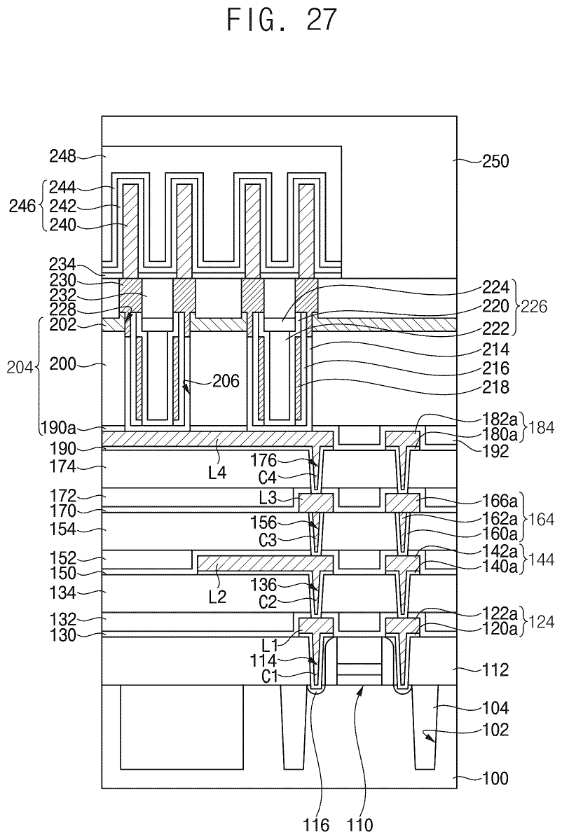

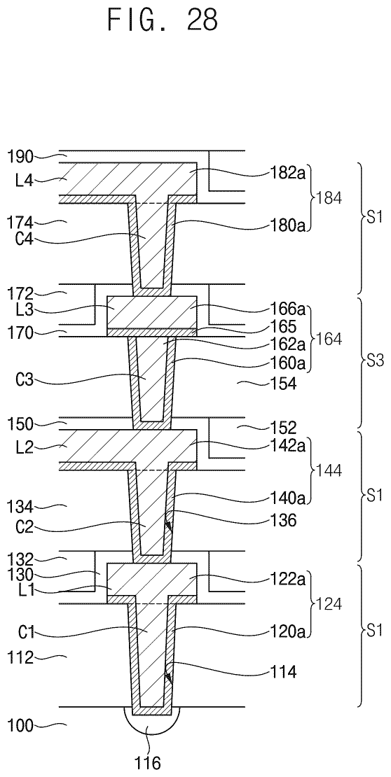

Referring to FIG. 27, a fifth etch stop layer 234 may be formed on the landing pads 230 and the upper insulation pattern 232.

Capacitors 246 may be formed through the fifth etch stop layer 234, and may contact upper surfaces of the landing pads 230, respectively. The capacitor 246 may include a lower electrode 240, a dielectric layer 242, and an upper electrode 244.

In an example embodiment, a support layer pattern connecting sidewalls of the lower electrode 240 may be further formed.

A plate electrode layer 248 may be formed on the upper electrode 244. The plate electrode layer 248 may include silicon germanium.

The capacitor 246 and the plate electrode layer 248 may be formed only on a memory cell region.

An upper insulating interlayer 250 may be formed on the plate electrode layer 248 and the upper insulation pattern 232. In an example embodiment, interconnections may be further formed through the upper insulating interlayer on a region except to the memory cell region. The interconnections may be connected to the lower wiring structure.

FIG. 28 is an enlarged cross-sectional view illustrating a lower wiring structure in a semiconductor device according to an example embodiment.

The semiconductor device may be the same as the semiconductor device shown in FIGS. 1 to 4, except for a lower wiring structure. Therefore, only the lower wiring structure may be described with reference to FIG. 28.

Referring to FIG. 28, the lower wiring structure may include the first to fourth wirings 124, 144, 164, and 184 stacked in the vertical direction.

According to an embodiment illustrate in FIG. 28, at least one of the first to fourth wirings 124, 144, 164, and 184 included in the lower wiring structure may have the first stacked structure S1, and at least one of the first to fourth wirings 124, 144, 164, and 184 included in the lower wiring structure may have a third stacked structure S3 that is different from the first stacked structure S1. Here, the third stacked structure S3 may also be different from the second stacked structure S2.

For example, a contact plug included in a wiring having the third stacked structure S3 may include a lower barrier metal pattern on a sidewall and a bottom of the contact hole and a lower metal pattern provided on the lower barrier metal pattern. The lower metal pattern may fill the contact hole. A conductive pattern included in the wiring of the third stacked structure may include an upper barrier metal pattern and an upper conductive pattern. The upper barrier metal pattern may be further provided on a bottom of the upper conductive pattern, and may contact the bottom of the upper conductive pattern. For example, the upper barrier metal may be sandwiched between the upper conductive pattern and the lower metal pattern in the vertical direction.

Each of the lower barrier metal pattern, the lower metal pattern and the upper barrier metal pattern may include metals formed by the chemical vapor deposition process. The upper metal pattern may include a metal formed by the physical vapor deposition process.

That is, the wiring having the third stacked structure S3 may be the same as the wiring of the second stacked structure S2, except that the conductive pattern on the contact plug may further include the upper barrier metal pattern.

In the third stacked structure S3, a material of the conductive pattern may have a resistance lower than a resistance of a material of the contact plug.

In an example embodiment, as shown in FIG. 28, the third wiring 164 may have the third stacked structure S3. The third wiring 164 includes a third contact plug C3 including the lower barrier metal pattern 160a and the lower metal pattern 162a, and a third conductive pattern L3 including the upper barrier metal pattern 165, and the upper metal pattern 166a.

In an example embodiment, the lower wiring structure included in the semiconductor device may have various structures in which at least one of the wirings has the third stacked structure. For example, in the lower wiring structure included in the semiconductor device shown in FIGS. 5 to 8, the wiring having the second stacked structure may be replaced with the wiring having the third stacked structure.

The semiconductor device may have the cell structure as described with reference to FIGS. 3 and 4 on the lower wiring structure.

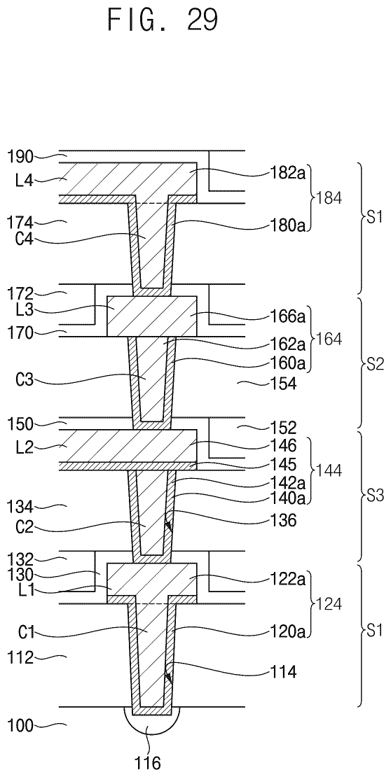

FIG. 29 is an enlarged cross-sectional view illustrating a lower wiring structure in a semiconductor device according to an example embodiment.

The semiconductor device may be the same as the semiconductor device shown in FIGS. 1 to 4, except for a lower wiring structure. Therefore, only the lower wiring structure may be described with reference to FIG. 29.

Referring to FIG. 29, the lower wiring structure may include the first to fourth wirings 124, 144, 164, and 184 stacked in the vertical direction.

According to an example embodiment, at least one of the first to fourth wirings 124, 144, 164, and 184 included in the lower wiring structure may have the first stacked structure S1, at least one of the first to fourth wirings 124, 144, 164, and 184 included in the lower wiring structure may have the second stacked structure S2, and least one of the first to fourth wirings 124, 144, 164, and 184 included in the lower wiring structure may have the third stacked structure S3.

A material of the conductive pattern in the second stacked structures S2 may have a resistance lower than a material of the contact plug in the second stacked structures S2. A material of the conductive pattern in the third stacked structures S3 may have a resistance lower than a material of the contact plug in the third stacked structures S3.

In an example embodiment, as shown in FIG. 29, the first and fourth wirings 124 and 184 may have the first stacked structure S1, and the second wirings 144 may have the third stacked structure S3. The third wiring 164 may have the second stacked structure S2. The second wiring 144 may include the second contact plug C2 including the lower barrier metal pattern 140a and the lower metal pattern 142a, and the second conductive pattern L2 including the upper barrier metal pattern 145, and the upper metal pattern 146a. The third wiring 164 may include the third contact plug C3 including the barrier metal pattern 160a and the lower metal pattern 162a, and the third conductive pattern L3 including the upper metal pattern 166a.

In an example embodiment, the lower wiring structure included in the semiconductor device may have various structures including wirings including the first to third stacked structures.

The semiconductor device may have the cell structure as described with reference to FIGS. 3 and 4 on the lower wiring structure.

The semiconductor device in which memory cells are provided on the lower wiring structure may include the lower wiring structure according to an example embodiment. Additionally, the semiconductor devices in accordance with embodiments may be used as memories included in electronic products such as mobile devices, memory cards, and computers.

The foregoing is illustrative of an example embodiment of the inventive concept and is not to be construed as limiting thereof. Although a few example embodiments have been described, those skilled in the art will readily appreciate that many modifications are possible in the example embodiments without materially departing from the scope of the inventive concept. Accordingly, all such modifications are intended to be included within the scope of the inventive concept as set forth in the claims.

What is claimed is:

1. A semiconductor device comprising:
a first wiring structure on a substrate, the first wiring structure comprising a plurality of wirings, each of the plurality of wirings comprising a contact plug and a conductive pattern stacked in a vertical direction perpendicular to a surface of the substrate; and
a cell structure provided on an uppermost conductive pattern in the first wiring structure, the cell structure comprising a vertical channel transistor connected to the conductive pattern,
wherein the plurality of wirings of the first wiring structure comprises:
a first wiring group comprising one or more first wirings, among the plurality of wirings, having a first stacked structure, the first stacked structure comprising a metal pattern and a barrier metal pattern constituting the contact plug and the conductive pattern, and the barrier metal pattern surrounding a lower surface of the metal pattern; and
a second wiring group comprising one or more second wirings, among the plurality of wirings, having a second stacked structure different from the first stacked structure, the second stacked structure comprising a lower metal pattern and a lower barrier metal pattern surrounding a lower surface of the lower metal pattern constituting the contact plug, and an upper metal pattern constituting the conductive pattern, the upper metal pattern having a resistance lower than the lower metal pattern.

2. The semiconductor device of claim 1, wherein the lower metal pattern comprises a first metal having first characteristics corresponding to a first deposition process and the upper metal pattern comprises a second metal having second characteristics corresponding to a second deposition process different from the first deposition process.

3. The semiconductor device of claim 1, wherein the lower metal pattern comprises a first metal material formed by a chemical vapor deposition process, and the upper metal pattern comprises a second metal material formed by a physical vapor deposition process.

4. The semiconductor device of claim 1, wherein the metal pattern comprises a metal material formed by a chemical vapor deposition process.

5. The semiconductor device of claim 1, wherein the lower metal pattern and the upper metal pattern comprise a same material.

6. The semiconductor device of claim 5, wherein the lower metal pattern and the upper metal pattern have different grain sizes.

7. The semiconductor device of claim 1, wherein the lower metal pattern and the upper metal pattern comprise tungsten.

8. The semiconductor device of claim 1, further comprises an upper barrier metal pattern provided on a bottom of the upper metal pattern.

9. The semiconductor device of claim 1, wherein the vertical channel transistor comprises:
a channel pattern that contacts the uppermost conductive pattern of the first wiring structure and comprises a sidewall extending in the vertical direction; and
a gate insulation layer pattern and a word line pattern laterally stacked on an inner wall of the channel pattern.

10. The semiconductor device of claim 9, wherein the channel pattern comprises an oxide semiconductor.

11. The semiconductor device of claim 1, further comprising a capacitor connected to the vertical channel transistor.

12. The semiconductor device of claim 1, further comprising a peripheral circuit structure comprises a plurality of peripheral circuits provided on the substrate.

13. A semiconductor device comprising:
a first wiring structure on a substrate, the first wiring structure comprising a plurality of wirings, each of the plurality of wirings comprising a contact plug and a conductive pattern stacked in a vertical direction perpendicular to a surface of the substrate;
a channel pattern provided on the first wiring structure, the channel pattern comprising two or more sidewalls extending in the vertical direction and a lower surface connecting lower portions of two opposing sidewalls, among the two or more sidewalls, in a horizontal direction, the lower surface of the channel pattern contacting an uppermost conductive pattern in the first wiring structure;
a gate insulation layer pattern and a word line pattern laterally stacked on an inner wall of the channel pattern; and
a capacitor connected to an upper surface of the channel pattern,
wherein the plurality of wirings of the first wiring structure comprises:
a first wiring group comprising one or more first wirings, among the plurality of wirings, having a first stacked structure, the first stacked structure comprising a metal pattern and a barrier metal pattern constituting the contact plug and the conductive pattern, and the barrier metal pattern surrounding a lower surface of the metal pattern; and
a second wiring group comprising one or more second wirings, among the plurality of wirings, having a second stacked structure different from the first stacked structure, the second stacked structure comprising a lower metal pattern and a lower barrier metal pattern surrounding a lower surface of the lower metal pattern constituting the contact plug, and an upper metal pattern constituting the conductive pattern, the upper metal pattern formed by a physical vapor deposition process.

14. The semiconductor device of claim 13, wherein the lower metal pattern and the metal pattern comprise a metal material formed by a chemical vapor deposition process.

15. The semiconductor device of claim 13, wherein the lower metal pattern and the upper metal pattern comprise tungsten.

16. The semiconductor device of claim 13, further comprising a first insulating interlayer provided on the first wiring structure,
wherein a portion of a bottom of the upper metal pattern wiring contacts the first insulating interlayer.

17. The semiconductor device of claim 16, further comprising an etch stop layer provided on surfaces of the conductive pattern of each of the plurality of wirings and the first insulating interlayer in which the contact plug is formed.

18. The semiconductor device of claim 13, wherein the channel pattern comprises an oxide semiconductor.

19. A semiconductor device, comprising:
a peripheral circuit structure comprising a plurality of peripheral circuits provided on a substrate;
a first wiring structure comprising a plurality of wirings connected to the plurality of peripheral circuit structures, each of the plurality of wirings comprising a contact plug and a conductive pattern stacked in a vertical direction perpendicular to the surface of the substrate, and an uppermost conductive pattern in the first wiring structure having a line shape extending in a first direction parallel with a surface of the substrate;
a channel pattern provided on the first wiring structure, the channel pattern comprising two or more sidewalls extending in the vertical direction and a lower surface connecting lower portions of two opposing sidewalls, among the two or more sidewalls, in a horizontal direction, and the channel pattern regularly arranged in the first direction and a second direction perpendicular to the first direction, the lower surface of the channel pattern contacting an uppermost conductive pattern in the first wiring structure;
a word line pattern formed laterally on an inner wall of the channel pattern, the word line extending in the second direction;
a gate insulation layer pattern between the channel pattern and the word line, the gate insulation layer pattern extending in the second direction; and
a capacitor connected to an upper surface of the channel pattern,
wherein the plurality of wirings of the first wiring structure comprises:
a first wiring group comprising one or more first wirings, among the plurality of wirings, having a first stacked structure, the first stacked structure comprising a metal pattern and a barrier metal pattern constituting the contact plug and the conductive pattern, and the barrier metal pattern surrounding a lower surface of the metal pattern; and
a second wiring group comprising one or more second wirings, among the plurality of wirings, having a second stacked structure different from the first stacked structure, the second stacked structure comprising a lower metal pattern formed by a chemical vapor deposition process and a lower barrier metal pattern surrounding a lower surface of the lower metal pattern constituting the contact plug, and an upper metal pattern formed by a physical vapor deposition process constituting the conductive pattern.

20. The semiconductor device of claim 19, wherein the channel pattern comprises an oxide semiconductor.
